(19) United States
(12) Patent Application Publication
(10) Pub. No.: US 2012/0073634 A1
(43) Pub. Date: Mar. 29, 2012

(54) Solar Cells and Solar Cell Arrays

(76) Inventor: Serguei Okhonin, Lausanne (CH)

(21) Appl. No.: 13/236,707

(22) Filed: Sep. 20, 2011

Related U.S. Application Data
(60) Provisional application No. 61/387,501, filed on Sep. 29, 2010.

(51) Int. Cl. H01L 31/02

(52) U.S. Cl. 136/252

(57) ABSTRACT

A solar cell disposed in a substrate, the solar cell comprising (A) a first sub-cell having a conductor disposed in the substrate which is adapted to receive a first voltage, a collection region, and an insulating layer disposed on the conductor and (i) between the conductor and the collection region and (ii) between the conductor and the substrate, and (B) a second sub-cell, having a conductor disposed in the substrate which is adapted to receive a second voltage, a collection region, and an insulating layer disposed (i) between the conductor and collection region and (ii) between the conductor and substrate. The ratio of a depth of the conductors to a width of the conductors is greater than or equal to 10:1; in one embodiment, a distance between the first and second sub-cells is greater than the sum of the widths of depletion/inversion layers formed during operation.

### RELATED APPLICATION

This non-provisional application claims priority to U.S. Provisional Application No. 61/387,501, entitled “Solar Cells and Solar Cell Arrays”, filed Sep. 29, 2010; the contents of this U.S. Provisional Patent Application are incorporated by reference herein in their entirety.

### INTRODUCTION

There are many inventions described and illustrated herein, as well as many aspects and embodiments of those inventions. In one aspect, the present inventions relate to, among other things, a solar cell to convert energy from light (for example, the sun) into electricity. In another aspect, the present inventions relate to a cell array having a plurality of solar cells wherein each cell converts energy from light (for example, the sun) into electricity. In yet another embodiment, the present inventions relate to a die or device having a solar cell array portion and an integrated circuit portion wherein the solar cell array portion includes a plurality of cells to convert energy from light into electricity.

In addition, the present inventions also relate to method of control and manufacturing such cell, cell array and die having a cell array portion and an integrated circuit portion.

In another aspect, the present inventions are directed to a light sensor comprised of one or more of the solar and/or sub-cells described and/or illustrated herein. Moreover the light sensor may be a discrete device and/or embedded or integrated with one or more solar cells or solar cell arrays; in addition thereto, or in lieu thereof, the light sensor may be embedded or integrated with circuitry.

### SUMMARY

There are many inventions described and illustrated herein. The present inventions are neither limited to any single aspect nor embodiment thereof, nor to any combinations and/or permutations of such aspects and/or embodiments. Moreover, each of the aspects of the present inventions, and/or embodiments thereof, may be employed alone or in combination with one or more of the other aspects of the present inventions and/or embodiments thereof. For the sake of brevity, many of those permutations and combinations will not be discussed separately herein.

Importantly, this Summary may not be reflective of or correlate to the inventions protected by the claims in this or continuation/divisional applications hereof. Even where this Summary is reflective of or correlates to the inventions protected by the claims hereof, this Summary may not be exhaustive of the scope of the present inventions.

In a first aspect, the present inventions are directed to a solar cell disposed in a substrate, the solar cell comprising first and second sub-cells, each disposed in the substrate and each including: a conductor disposed in the substrate, wherein the conductor is adapted to receive a predetermined voltage, a collection region disposed in the substrate, and an insulating layer disposed on the associated conductor and (i) between the associated conductor and the associated collection region and (ii) between the associated conductor and the substrate. The ratio of the depth of the conductor of the first sub-cell within the substrate to the width of the conductor of the first sub-cell within the substrate is greater than or equal to 10:1; and a length between the first sub-cell and the second sub-cell is greater than the sum of the widths of depletion/inversion layers formed in relation to the first and second sub-cells during operation.

In one embodiment of this aspect of the present inventions, the collection region of the first sub-cell is disposed substantially around and on the associated insulating layer, and the collection region of the second sub-cell is disposed substantially around and on the associated insulating layer. In another embodiment, the collection region of the first and second sub-cells each includes a plurality of sub-regions disposed around and on the associated insulating layer. In yet another embodiment, the insulating regions of the first and second sub-cells may surround the associated conductor and each collection region of the first and second sub-cells is juxtaposed the associated insulating layer.

In one preferred embodiment, the ratio of the depth of the conductor of the first sub-cell within the substrate to the width of the conductor of the first sub-cell within the substrate is greater than or equal to 25:1. Indeed, in a more preferred embodiment. The ratio of the depth of the conductor of the first sub-cell within the substrate to the width of the conductor of the first sub-cell within the substrate is greater than or equal to 50:1.

Notably, the solar cell may include an anti-reflective material disposed on an exposed surface of the substrate.

The collection regions of each of the sub-cells may include a plurality of sub-regions disposed around and on the associated insulating layer wherein the plurality of sub-regions of the collection region of the first sub-cell are laterally offset in relation to the plurality of sub-regions of the collection region of the second sub-cell.

In a second aspect, the present inventions are directed to a solar cell disposed in a semiconductor substrate, the solar cell comprising: a first sub-cell, disposed in the semiconductor substrate, including a first conductor disposed in the semiconductor substrate, wherein the first conductor is adapted to receive a first predetermined voltage, a first collection region disposed in the semiconductor substrate, and a first insulating layer disposed on the first conductor and (i) between the first conductor and the first collection region and (ii) between the first conductor and the semiconductor substrate, wherein the first collection region is juxtaposed the first insulating layer. The present invention of this aspect further includes a second sub-cell, disposed in the semiconductor substrate and separated from the first sub-cell by a predetermined length. The second sub-cell includes a second conductor disposed in the semiconductor substrate, wherein the second conductor is adapted to receive a second predetermined voltage, a second collection region disposed in the semiconductor substrate, and a second insulating layer disposed (i) between the second conductor and the second collection region and (ii) between the second conductor and the semiconductor substrate, wherein the second collection region is juxtaposed the second insulating layer. The present invention of this aspect also includes a ratio of a depth of the conductor of the first sub-cell within the semiconductor substrate to a width of the conductor of the first sub-cell within the semiconductor substrate is greater than or equal to 10:1.

Notably, in one preferred embodiment, the ratio of the depth of the conductor of the first sub-cell within the substrate to the width of the conductor of the first sub-cell within the substrate is greater than or equal to 25:1. Indeed, in a more preferred embodiment, the ratio is greater than or equal to 50:1.

The first and second conductors may be metal, metal compound and/or one or more semiconductors doped with one or more impurities. The first and second collection regions may be regions of the semiconductor substrate that are doped with one or more impurities. The first and second insulating layers may include silicon oxide, silicon nitride and/or combination thereof.

In one embodiment of this aspect of the present inventions, the collection region of the first sub-cell is disposed substantially around and on the associated insulating layer, and the collection region of the second sub-cell is disposed substantially around and on the associated insulating layer. In another embodiment, the collection region of the first and second sub-cells each includes a plurality of sub-regions disposed around and on the associated insulating layer. In yet another embodiment, the insulating regions of the first and second sub-cells may surround the associated conductor and each collection region of the first and second sub-cells is juxtaposed the associated insulating layer.

In a third aspect, the present inventions are directed to a solar cell system comprising a solar cell including a first sub-cell, disposed in the semiconductor substrate, including a first conductor disposed in the semiconductor substrate, wherein the first conductor is adapted to receive a first predetermined voltage, a first collection region disposed in the semiconductor substrate and a first insulating layer disposed (i) on and surrounding the first conductor within the semiconductor substrate to insulate the first conductor from the semiconductor substrate and (ii) between the first conductor and the first collection region to insulate the first conductor from the first collection region. The solar cell further includes a second sub-cell, disposed in the semiconductor substrate and separated from the first sub-cell by a predetermined length, the second sub-cell includes a second conductor disposed in the semiconductor substrate, wherein the second conductor is adapted to receive a second predetermined voltage, a second collection region disposed in the semiconductor substrate and a second insulating layer disposed (i) on and surrounding the second conductor within the semiconductor substrate to insulate the second conductor from the semiconductor substrate and (ii) between the second conductor and the second collection region to insulate the second conductor from the second collection region. The ratio of a depth of the conductor of the first sub-cell within the semiconductor substrate to a width of the conductor of the first sub-cell within the semiconductor substrate and the ratio of a depth of the conductor of the second sub-cell within the semiconductor substrate to a width of the conductor of the second sub-cell within the semiconductor substrate are each greater than or equal to 10:1.

The solar cell system may include a voltage generator, coupled to the first and second conductors, to generate the first and second predetermined voltages. In one embodiment, the first predetermined voltage is positive and the second predetermined voltage is negative.

Notably, in one preferred embodiment, the ratio of the depth of the conductor of the first sub-cell within the substrate to the width of the conductor of the first sub-cell within the substrate is greater than or equal to 25:1. Indeed, in a more preferred embodiment, the ratio is greater than or equal to 50:1.

As stated herein, there are many inventions, and aspects of the inventions, described and illustrated herein. This Summary is not exhaustive of the scope of the present inventions. Indeed, this Summary may not be reflective of or correlate to the inventions protected by the claims in this or continuation/divisional applications hereof.

Moreover, this Summary is not intended to be limiting of the inventions or the claims (whether the currently presented claims or claims of a divisional/continuation application) and should not be interpreted in that manner. While certain embodiments have been described and/or outlined in this Summary, it should be understood that the present inventions are not limited to such embodiments, description and/or outline, nor are the claims limited in such a manner (which should also not be interpreted as being limited by this Summary).

Indeed, many other aspects, inventions and embodiments, which may be different from and/or similar to, the aspects, inventions and embodiments presented in this Summary, will be apparent from the description, illustrations and claims hereof. In addition, although various features, attributes and advantages have been described in this Summary and/or are apparent in light thereof, it should be understood that such features, attributes and advantages are not required in any of the embodiments of the present inventions and, indeed, need not be present/incorporated in any of the embodiments of the present inventions.

### BRIEF DESCRIPTION OF THE DRAWINGS

In the course of the detailed description to follow, reference will be made to the attached drawings. These drawings show different aspects of the present inventions and, where appropriate, reference numerals illustrating like structures, components, materials and/or elements in different figures are labeled similarly. It is understood that various combinations of the structures, components, and/or elements, other than those specifically shown, are contemplated and are within the scope of the present inventions.

Moreover, there are many inventions described and illustrated herein. The present inventions are neither limited to any single aspect nor embodiment thereof, nor to any combinations and/or permutations of such aspects and/or embodiments. Moreover, each of the aspects of the present inventions, and/or embodiments thereof, may be employed alone or in combination with one or more of the other aspects of the present inventions and/or embodiments thereof. For the sake of brevity, certain permutations and combinations are not discussed and/or illustrated separately herein.

FIG. 1A illustrates a top view of an exemplary solar cell according to certain aspects and embodiments of the present inventions wherein the solar cell in this exemplary embodiment includes first and second sub-cells each having a conductor, insulating material (for example, dielectric) and a collection region (for example, a semiconductor region which may be doped with one or more impurities); notably, the solar cell may include more than two sub-cells;

FIGS. 1B, 1C and 2A illustrate cross-sectional views of a portion of the exemplary solar cell of FIG. 1A (along dotted line A-A), wherein FIG. 1B illustrates various physical or layout parameters including width and depth of the sub-cells within the substrate and length between sub-cells of a solar cell, FIG. 1C illustrates an exemplary solar cell including an anti-reflective material disposed over portions of the solar cell which may enhance the efficiency and/or operation of the solar cell, and FIG. 2A generally illustrates the formation of an inversion or accumulation layer or region, in connection with the sub-cells of the solar cell, during operation, in accordance with certain aspects of the present inventions;

FIG. 2B depicts the general operation of the solar cell, in accordance with certain aspects of the present inventions, when a first voltage (for example, positive voltage) is applied to the conductor of the first sub-cell and a second voltage (for example, negative voltage) is applied to the conductor of the second sub-cell; under these circumstances, an electric field forms and, in response to incident photons from one or more light sources (for example, the sun), electrons (e−) and holes (h+) are generated within the substrate; as such, the electrons (e−) are attracted to the first sub-cell and the holes (h+) are attracted to the second sub-cell; the electrons (e−) tend to move or be attracted to the n+ region(s) via the inversion or accumulation layer which forms juxtaposed the dielectric layer or material of the first sub-cell of the solar cell; similarly, the holes (h+) tend to move or be attracted to the p+ region(s) via the inversion or accumulation layer which forms juxtaposed the dielectric layer or material of the second sub-cell of the solar cell;

FIG. 3 illustrates a top view layout of a solar cell of FIG. 1A in conjunction with conductors which couple to collection regions of the sub-cells to an output, in accordance with certain aspects of the present inventions; moreover, voltage generator circuitry generates the first and second operating voltages applied to the conductors of the sub-cells; notably, the voltage generator circuitry may be any circuitry and/or employ any technique now known or later developed to generate the first and second voltages (for example, the a solar cell, a battery and/or a capacitor such as, for example, an ultra-capacitor);

FIGS. 4A and 4B illustrate top views of exemplary solar cells according to certain aspects and embodiments of the present inventions wherein the sub-cells of the solar cell illustrated in FIG. 4A include semiconductor collection regions that partially surround the associated conductor, and the sub-cells illustrated in FIG. 4B include semiconductor collection regions that partially surround the associated conductor and include a plurality of sub-regions in an “island” configuration/layout;

FIGS. 5A and 5B illustrate cross-sectional views of a portion of the exemplary solar cell of FIG. 4B (along dotted line A-A and B-B, respectively), in accordance with certain aspects of the present inventions;

FIG. 6 illustrates a top view layout of a solar cell of FIG. 5B in conjunction with conductors which couple collection regions of the sub-cells to an output, in accordance with certain aspects of the present inventions; notably, voltage generator circuitry generates the first and second operating voltages applied to the conductors of the sub-cells;

FIGS. 7A and 7B illustrate top view layouts of the solar cell of the type illustrated in FIG. 5B wherein the solar cell includes three sub-cells, in accordance with certain aspects of the present inventions; notably, any type of the solar cells of the present inventions (for example, those illustrated in FIGS. 1A and 4A) may be implemented in the more than two sub-cell solar cell architecture;

FIGS. 7C and 7D illustrate top view layouts of the solar cell of the type illustrated in FIGS. 5B and 1A, respectively, wherein the solar cell includes more than two sub-cells, in accordance with certain aspects of the present inventions; notably, any of the solar cell architectures of the present inventions (for example, the cell architecture illustrated in FIG. 4A) may be implemented in the more than two sub-cell solar cell architecture; notably, a plurality of sub-cells may couple to a first voltage (for example, a positive voltage) and a plurality may couple to a second voltage (for example, a negative voltage); in one embodiment, the solar cell may include an equal number of sub-cells couple to the first and second voltages; in another embodiment, the solar cell may include more sub-cells coupled to a positive or negative voltage (see, FIGS. 7A and 7B);

FIGS. 8A, 8B, 14A and 14B illustrate a top view block form, a solar cell and/or solar cell array integrated with integrated circuits (for example, CMOS transistors) or other active components; notably, such circuits and other components may be integrated or fabricated into selected portions of the die/device using standard fabrication techniques and/or techniques employed to fabricate the solar cell and solar cell array; notably, any of the solar cell configurations and solar cell array architectures (for example, cell architecture illustrated in FIG. 1A, 4A, 4B, 9, 11 and/or 20) may be integrated on a die/device with integrated circuitry as illustrated herein and in accordance with certain aspects of the present inventions;

FIG. 9 illustrates a top view of an exemplary solar cell according to certain aspects and embodiments of the present inventions wherein the solar cell in this exemplary embodiment includes first and second sub-cells having conductors comprised of different materials; notably, the solar cell of this embodiment may include more than two sub-cells; notably, in this embodiment, the conductors of the sub-cells may include different (i) work functions and/or (ii) charges contained therein wherein, in this way, one of the sub-cells of the solar cell may have a tendency to attract electrons (e−) and the other of the sub-cells may have a tendency to attract holes (h+);

FIG. 10A illustrates a cross-sectional view of a portion of the exemplary solar cell of FIG. 9 (along dotted line A-A), wherein, in operation, an inversion or accumulation layer or region forms, in accordance with certain aspects of the present inventions;

FIG. 10B depicts the general operation of the solar cell, in accordance with certain aspects of the present inventions, when a first voltage (for example, positive voltage) is applied to the conductor of the first sub-cell and a second voltage (for example, negative voltage) is applied to the conductor of the second sub-cell; under these circumstances, in response to incident photons from one or more light sources (for example, the sun), electrons (e−) and holes (h+) are generated within the substrate; as such, the electrons (e−) are attracted to the first sub-cell and the holes (h+) are attracted to the second sub-cell; the electrons (e−) tend to move or be attracted to the n+region(s) via the inversion or accumulation layer which forms juxtaposed the dielectric layer or material of the first sub-cell of the solar cell; similarly, the holes (h+) tend to move or be attracted to the p+ region(s) via the inversion or accumulation layer which forms juxtaposed the dielectric layer or material of the second sub-cell of the solar cell;

FIG. 11 illustrates a top view of exemplary solar cells according to certain aspects and embodiments of the present inventions wherein the sub-cells of the solar cell include semiconductor collection regions that partially surround the conductor and include a plurality of collection sub-regions in an “island” configuration/layout; notably, a solar cell including first and second sub-cells having conductors comprised of different materials may also include partially surrounding semiconductor collection regions like that in FIG. 9 or completely surrounding semiconductor collection regions like that in FIG. 1A;

FIGS. 12A and 12B illustrate cross-sectional views of a portion of the exemplary solar cell of FIG. 11 (along dotted line A-A and B-B, respectively), in accordance with certain aspects of the present inventions;

FIG. 13A illustrates a top view layout of a solar cell of FIG. 11 in conjunction with conductors which are coupled to collection regions of the sub-cells to output a voltage generated in response to incident photons from one or more light sources, in accordance with certain aspects of the present inventions;

FIGS. 13B and 13C illustrate top view layouts of the solar cell of the type illustrated in FIG. 11 wherein the solar cell include three or more sub-cells, in accordance with certain aspects of the present inventions;

FIG. 13D illustrate top view layouts of the solar cell of the type illustrated in FIG. 9 wherein the solar cell include three or more sub-cells, in accordance with certain aspects of the present inventions; notably, any type of semiconductor collection region layout of the sub-cells of the solar cells may be implemented (for example, those illustrated in FIG. 1A) may be implemented in a more than two sub-cell solar cell architecture;

FIGS. 15A and 15B illustrate a cross-sectional view of one or more solar cells integrated on a die or wafer with integrated circuitry, in accordance with certain aspects of the present inventions; in these illustrations, the die or wafer includes an anti-reflective material on a side of the die or wafer which is opposite the side in which the integrated circuitry is formed; notably, the first and second sub-cells may include conductors comprised of the same material (FIG. 15A) or different materials (FIG. 15B); notably, the solar cell of these embodiments may include more than two sub-cells; the one or more solar cells integrated on a die or wafer with integrated circuitry, in accordance with certain aspects of the present inventions, may or may not include anti-reflective material, wherein in those embodiments no anti-reflective material is employed, the incident surface may be the backside of the die/wafer or the front side of the die/wafer (which is opposite of the backside of the die/wafer);

FIGS. 16A and 16B illustrate a cross-sectional view of a solar cell wherein the conductors are arranged laterally (compare FIG. 1A), in accordance with certain aspects of the present inventions; in these illustrative embodiments an electric field is formed between the conductors of the solar cell A—here, conductor 1 and conductor 2; notably, the conductors adjacent to the conductors of the solar cell A may be conductors of the solar cell A or of adjacent solar cells; moreover, in FIG. 16B, the die or wafer includes an anti-reflective material disposed over portions of the solar cell which may enhance the efficiency and/or operation of the solar cell;

FIGS. 17A and 17B illustrate the operation of the solar cell of FIGS. 16A and 16B, respectively, wherein an electric field forms or is induced between the conductors of the solar cell, in accordance with certain aspects of the present inventions; here, in response to incident photons from one or more light sources, electrons (e−) and holes (h+) are generated within the substrate which, in view of the induced electric field, electrons (e−) are attracted to the conductor 1 and the holes (h+) are attracted to conductor 2; also illustrated are the n+ region juxtaposed conductor 1 and the p+ region juxtaposed conductor 2 which are electrically coupled to the output (Vₒᵤₜₚᵤₜ) of the solar cell;

FIGS. 18A and 18B illustrate top view layouts of light sensors according to certain aspects of the present inventions wherein, in this exemplary illustrative embodiment, the light sensor includes, among other things, at least two sub-cells (as discussed above in the context of a solar cell); notably, in operation, a voltage Va>0 is applied to terminal A connected to a collection region of one of the sub-cells (in this exemplary embodiment, an n+ region) and a voltage Vb≦0 is applied to terminal B connected a collection region of the sub-cells (in this exemplary embodiment, a p+ region); here incident light induces a current between terminals A and B and, measurement circuitry determines the presences of light and/or the intensity of the light by measuring, sampling, determining and/or detecting the generated current (via the measurement circuitry, for example, a current-type sensor), notably, the sub-cells of the light sensor of the present inventions may include any of the features of the embodiments of the sub-cells of the solar cells as described and/or illustrated herein;

FIG. 18C illustrates a top view layout of a light sensor of FIG. 18B in conjunction with conductors which are coupled to collection regions of the sub-cells to output a current in response to incident photons from one or more light sources, in accordance with certain aspects of the present inventions;

FIG. 19 illustrates another light sensor embodiment, according to one aspect of the present inventions, in cross-sectional form; in this exemplary embodiment, in operation, n+ region can be grounded, a positive voltage is applied to p+ region, a negative voltage Vg1 is applied to the gate adjacent to n+ and a positive voltage Vg2 is applied to the gate Vg2 adjacent to p+, wherein a depletion layer may be created around p+ region and a current will flow between the terminals in the absence of sufficient light (i.e., the light is “off”); however, when sufficient light is incident on the sensor (i.e., the light is “on”), electrons created by incident photons will be accumulated under the gate adjacent to p+ and this will eventually trigger relatively large current between n+ and p+ contacts, wherein by measuring the triggering time the light intensity may be determined, detected, sampled obtained and/or acquired (via the measurement circuitry, for example, a circuit that measures or determines the triggering time of the sensor); and

FIG. 20 illustrates a cross-sectional view of a solar cell according to, for example, the top view illustration of, for example, FIGS. 1A, 4A, 7D and 13D wherein the collection regions which are coupled to the outputs via the conductors are formed from a metal or metal compound material, in accordance with certain aspects of the present inventions; in this embodiment, one or more (or all) of the n+ and p+ regions in the embodiments described and/or illustrated herein are substituted with a metal (for example, aluminum or copper) or metal compound; notably, the solar cell of FIG. 20 may be implemented in any of the embodiments and/or may implement any of the features of the embodiments described and/or illustrated herein.

Again, there are many inventions described and illustrated herein. The present inventions are neither limited to any single aspect nor embodiment thereof, nor to any combinations and/or permutations of such aspects and/or embodiments. Each of the aspects of the present inventions, and/or embodiments thereof, may be employed alone or in combination with one or more of the other aspects of the present inventions and/or embodiments thereof. For the sake of brevity, many of those combinations and permutations are not discussed separately herein.

### DETAILED DESCRIPTION

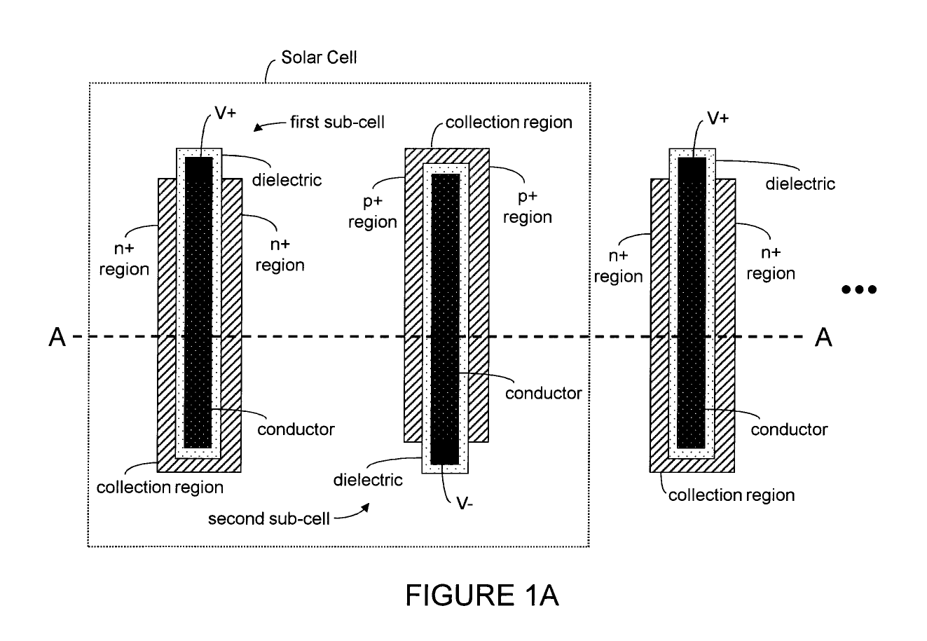

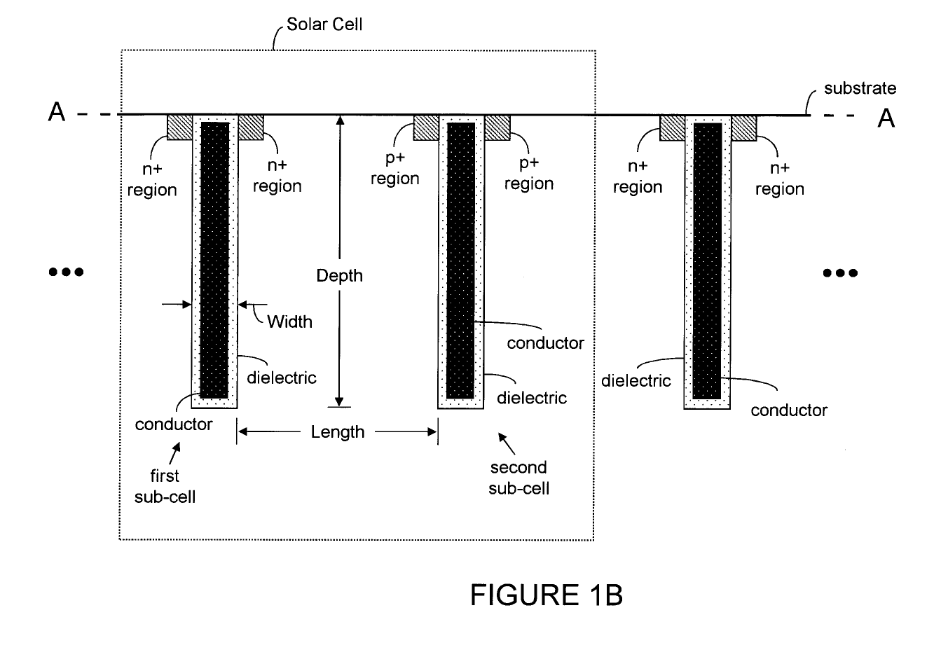

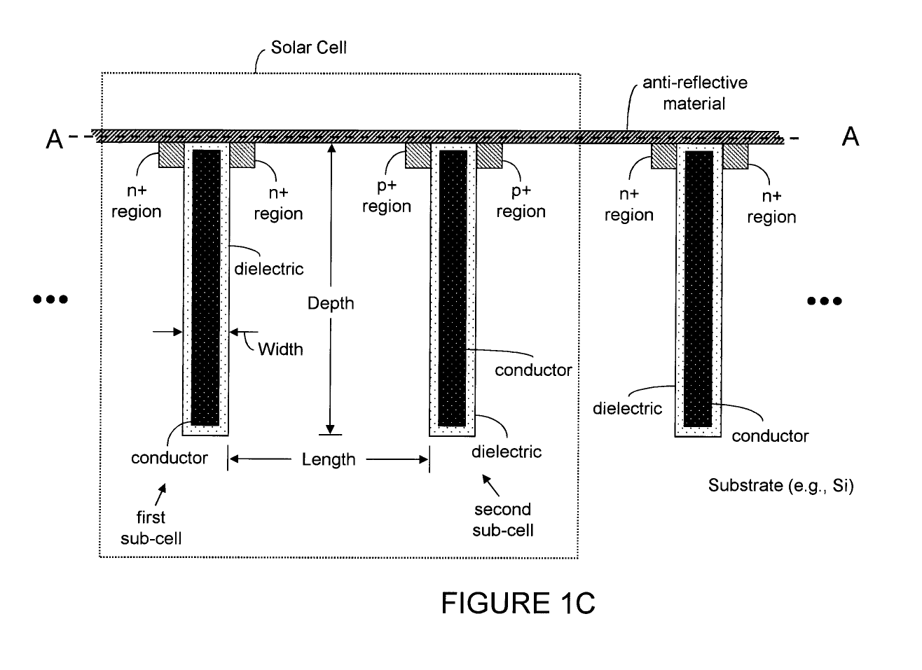

There are many inventions described and illustrated herein. In one aspect, the present inventions are directed to a solar cell and/or solar cell array, and method of fabricating and operating such a solar cell and/or solar cell array. With reference to FIGS. 1A and 1B, in a first embodiment, a solar cell according to an aspect of the present inventions includes at least two sub-cells wherein each sub-cell includes a conductor which is vertically disposed/formed in a substrate and insulated therefrom via an insulator or dielectric (for example, silicon oxide, silicon nitride and/or combination thereof). The conductor may be a material that provides or facilitates a charge to form therein or thereon—for example, a metal material (for example, aluminum or copper), metal compound material and/or a doped semiconductor material (for example, silicon doped with donor or acceptor type impurities).

Notably, the substrate may be one or more materials from the Group IV semiconductor including silicon (for example, bulk-silicon substrate), germanium, and silicon carbide or semiconductor-on-insulator substrate (for example, a silicon-on-insulator). The substrate may be an intrinsic material or a material having impurities, for example, n-type or p-type materials. In one embodiment the substrate is p-type silicon having N=10¹⁴ cm⁻³.

The solar cell also includes one or more electron and hole collection regions which, in one embodiment, are semiconductor regions that are doped with impurities (illustrated as n+ and p+ regions). In this illustrated embodiment, an n-type semiconductor material which provides or forms an n+ region that is juxtaposed the dielectric material of the first sub-cell. Similarly, a p-type semiconductor material which provides or forms a p+ region that is juxtaposed the dielectric material of the second sub-cell. The n-type semiconductor material may be formed from or by doping a semiconductor (for example, silicon) with an n-type impurity (for example, phosphorus or arsenic). The p-type semiconductor material may be formed from or by doping a semiconductor (for example, silicon) with a p-type impurity (for example, boron). Notably, the solar cell may be fabricated using any materials and/or techniques now known or later developed.

With continued reference to FIGS. 1A and 1B, first and/or second voltages are applied to the conductors of the sub-cells. For example, in one embodiment, the conductor of the first sub-cell is connected to a first voltage (e.g., V+) and the conductor of the second sub-cell is connected to a second voltage (e.g., V−). In this way, the conductor of the first sub-cell is at a first voltage (for example, a positive voltage) and the conductor of the second sub-cell is at a second voltage (for example, a negative voltage) which is different from the first voltage. In one embodiment, the first and second voltages are DC voltages.

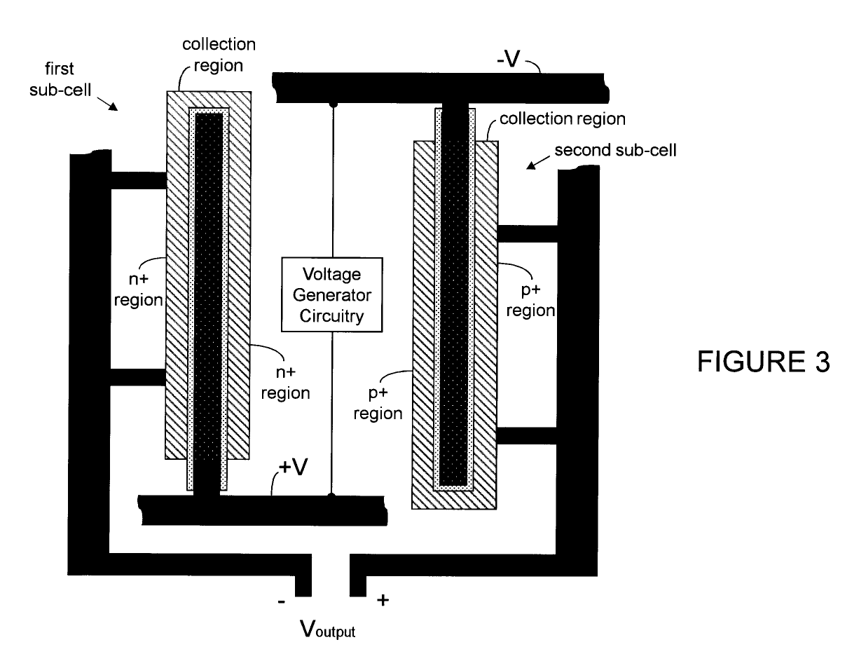

Notably, the first and second voltages may be generated by voltage generator circuitry. (See, for example, FIG. 3). Such voltage generator circuitry may be any circuitry and/or employ any technique now known or later developed to generate the first and second voltages. For example, the voltage generator circuitry may be a solar cell, a battery and/or a capacitor (for example, an ultra-capacitor).

With reference to FIG. 1B, in one exemplary embodiment, the physical properties and layout of the solar cell may include: (i) a “width” of the sub-cell which is about 0.1 μm, (ii) a “depth” of the sub-cell which is about 5 μm, and (iii) a distance between sub-cells (i.e., “length”) which is about 6 μm. In one preferred embodiment, the conductor of the sub-cell accounts for more than 80% of the width and depth of the sub-cell and, in a more preferred embodiment, the conductor of the sub-cell accounts for more than 90% of the width and depth of the sub-cell.

In addition, with continued reference to FIG. 1B, in one embodiment, the distance between sub-cells is configured or arranged to be greater than the sum of the width of the depletion and inversion layers (hereinafter collectively “depletion/inversion layer”) formed around the first sub-cell and the width of the depletion/inversion layer formed around the second sub-cell during operation. Notably, the layout parameters of the sub-cells and the solar cell are provided merely for exemplary purposes only and are not intended to limit the inventions. The inventions may be implemented using other layout parameters wherein certain considerations may dictate layout parameters that differ from the exemplary layout parameters. Thus, the present inventions described and/or illustrated herein may be implemented in conjunction with other layout parameters. Indeed, all layout parameters of the sub-cells and solar cells, consistent with the present inventions, are intended to fall within the scope of the present inventions.

For example, in one embodiment, the depth to width ratio of a sub-cell is greater than 10:1, and preferably 25:1 and more preferably 50:1. Similarly, the depth to width ratio of the conductor of a sub-cell is greater than 10:1, and preferably 25:1 and more preferably 50:1. In addition, in one embodiment, the length (i.e., the distance between associated sub-cells) is equal to at least the sum of the widths of the depletion/inversion layer formed in relation to sub-cells during operation and, preferably 25% greater than the sum of the widths of the depletion/inversion layer formed in relation to sub-cells during operation, and more preferably 50% greater than the sum of the widths of the depletion/inversion layer formed in relation to sub-cells during operation.

The layout of each sub-cell may be substantially identical or may be different. That is, in one embodiment, each sub-cell may have substantially identical depths and widths; in another embodiment, one, some or all of the sub-cells may have a depth and width which is different from other sub-cells. Moreover, the length between associated sub-cells of a solar cell may be substantially identical among the solar cells, for example of an array of solar cells, or such length may be different.

The solar cell may include an anti-reflective material disposed over portions of the solar cell, solar cell array and/or die/device. (See, for example, FIG. 1C). The anti-reflective material may enhance the efficiency of the solar cell. Although many of the embodiments do not illustrate an anti-reflective material, it should be noted that an anti-reflective material may be employed in any and/or all of the embodiments described and/or illustrated herein—even though such embodiments are not discussed and/or separately illustrated herein. Thus, an anti-reflective material/layer may be implemented in any and/or all of the embodiments and, accordingly, the embodiments including the anti-reflective material/layer fall within the scope of the present inventions.

Briefly, the solar cell and solar cell array of the present inventions may be fabricated using standard and well-known manufacturing processes and techniques. Such processes and techniques may be implemented on well-known fabrication equipment. Moreover, where the die/device also includes integrated circuits (for example, CMOS transistors) or other active components, such circuits and other components may be integrated or fabricated into selected portions of the die/device (for example portions not occupied by the portions of the solar cells and solar cell array) using well-known manufacturing fabrication techniques and equipment.

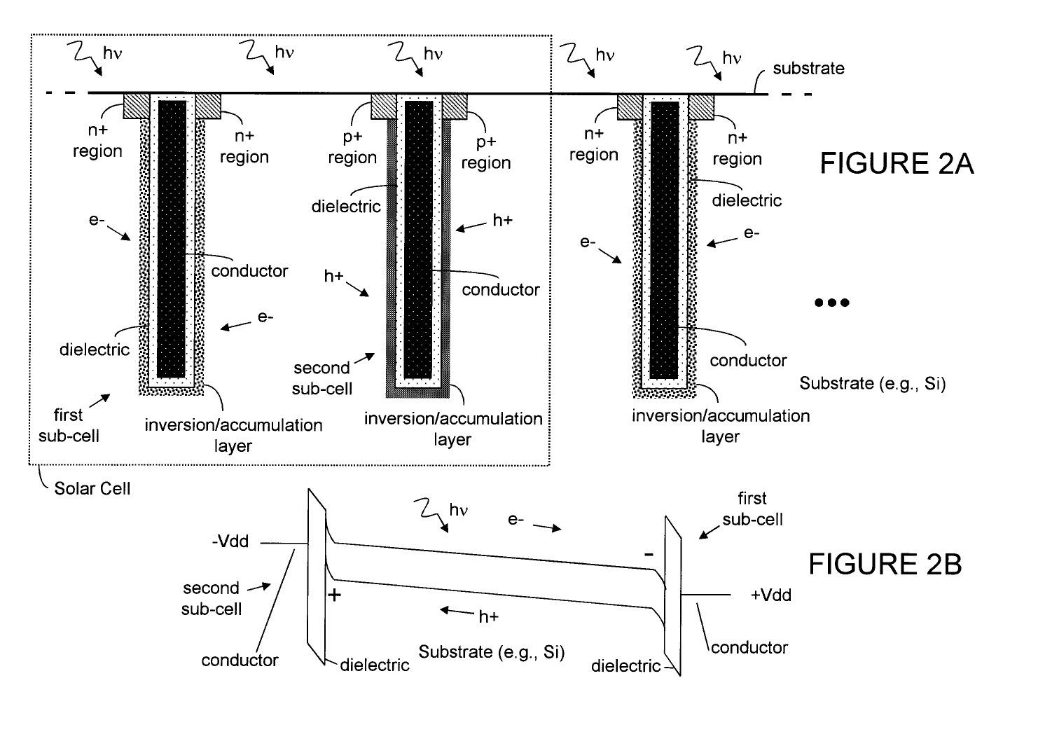

With reference to FIGS. 2A and 2B, in operation, a first voltage (for example, positive voltage) is applied to the conductor of the first sub-cell and a second voltage (for example, negative voltage) is applied to the conductor of the second sub-cell. In response to incident photons from one or more light sources (for example, the sun), electrons (e−) and holes (h+) are generated within the substrate. As such, the electrons (e−) are attracted to the first sub-cell and the holes (h+) are attracted to the second sub-cell. The electrons (e−) tend to move towards the n+ region(s) via the inversion or accumulation layer which forms juxtaposed the dielectric layer or material of the first sub-cell of the solar cell. Similarly, the holes (h+) tend to move towards the p+ region(s) via the inversion or accumulation layer which forms juxtaposed the dielectric layer or material of the second sub-cell of the solar cell. An electric field develops between sub-cells of a solar cell thereby promoting or inducing selective attraction of carriers (either holes (h+) or electrons (e−)) to the inversion/accumulation layer of a sub-cell.

The inversion or accumulation layers may provide a low resistance path for the movement of electrons (e−) and holes (h+), generated within the substrate in response to the incident photons, to the collection regions (n+ region and the p+ region of the sub-cells, respectively) of the sub-cells. Where the substrate includes little to no impurities and/or little to no additional doping relative to conventional IC substrates, the carrier lifetime may be quite high. Moreover, any interface defects may be screened by the inversion or accumulation layers associated with the sub-cells.

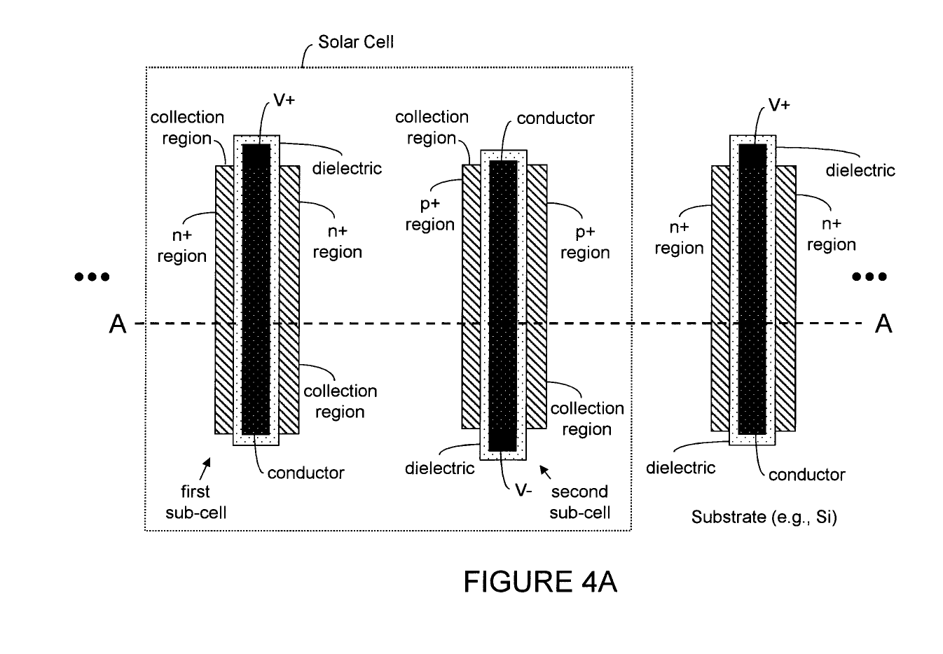

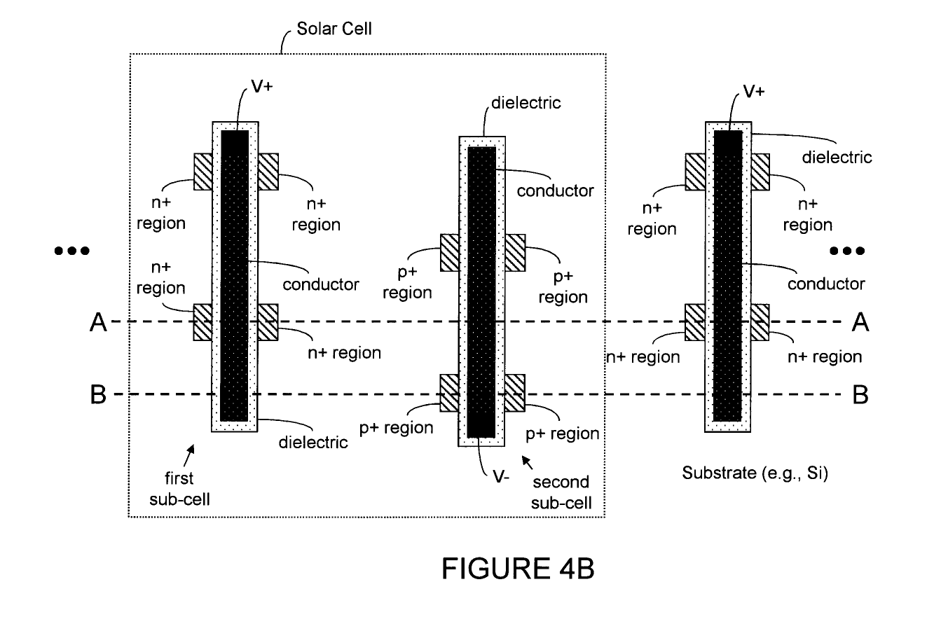

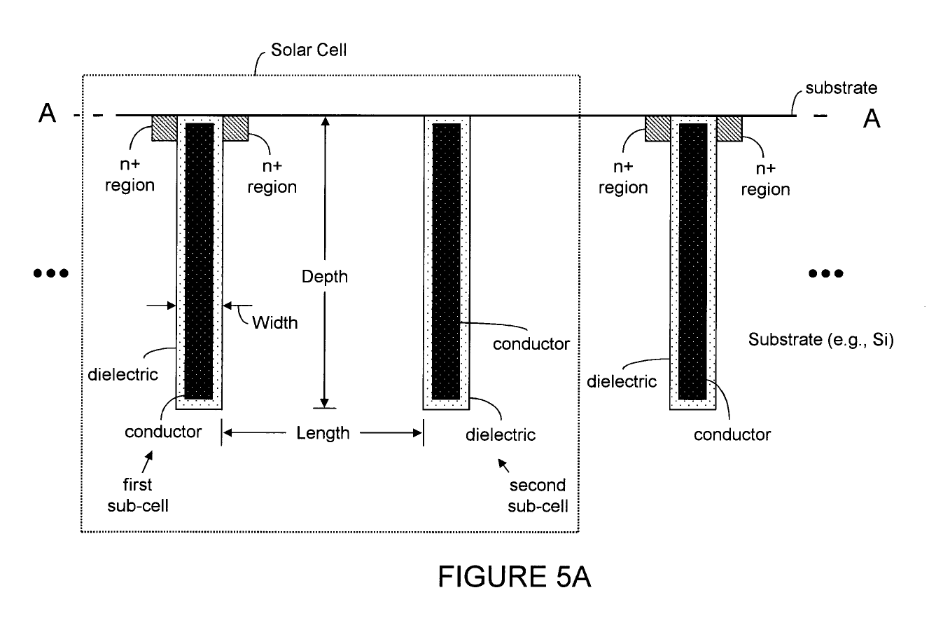

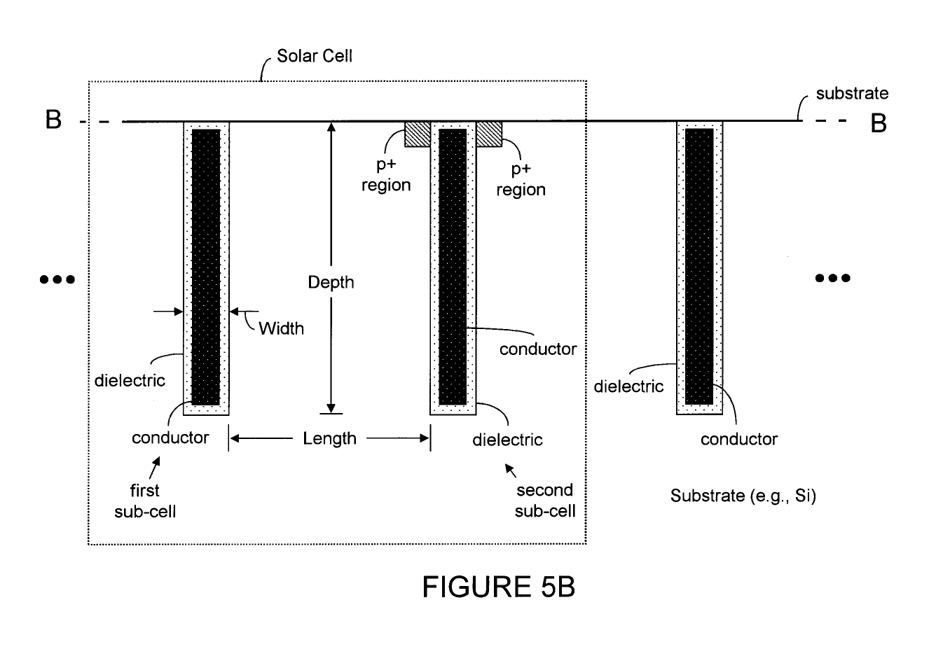

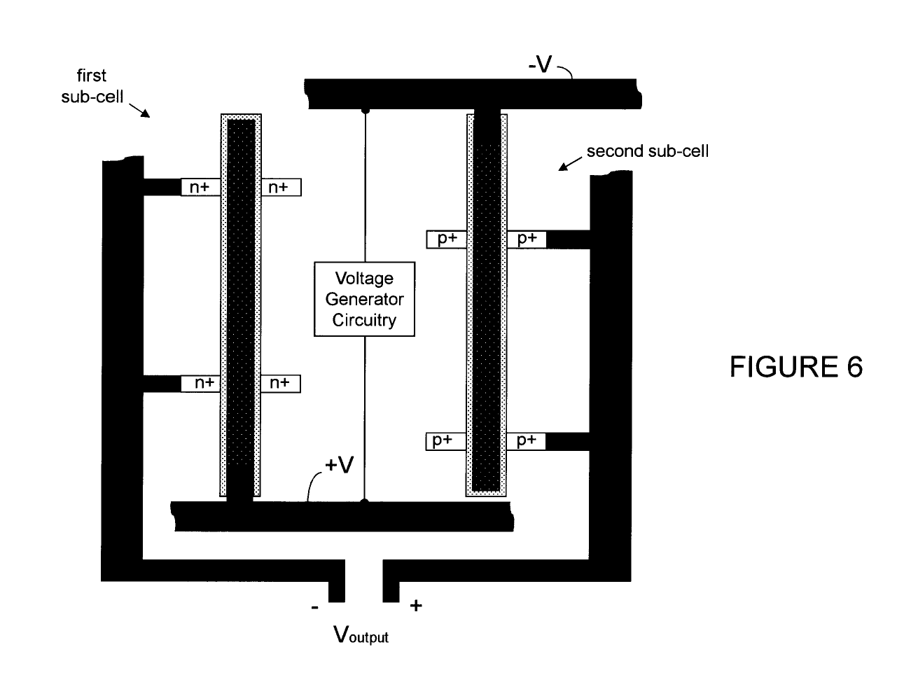

With reference to FIG. 3, in one embodiment, the collection regions may be coupled to an output. For example, n+ region of the first sub-cell and the p+ region of the second sub-cell are electrically coupled to the output (Vₒᵤₜₚᵤₜ) of the solar cell. Notably, the n+ region of the first sub-cell and the P+ region of the second sub-cell may be formed substantially around the conductor-dielectric structure (see, for example, FIGS. 1A and 4A) or may be formed as a plurality of sub-regions or “islands” at predetermined locations (see, for example, FIGS. 4B, 5A, 5B and 6). All configurations are intended to fall within the scope of the present inventions.

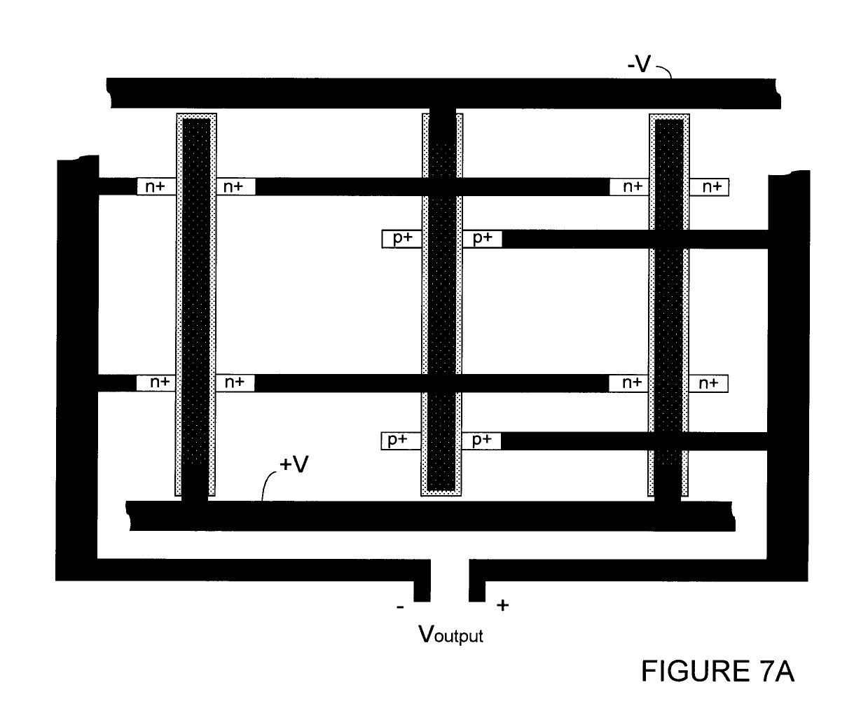

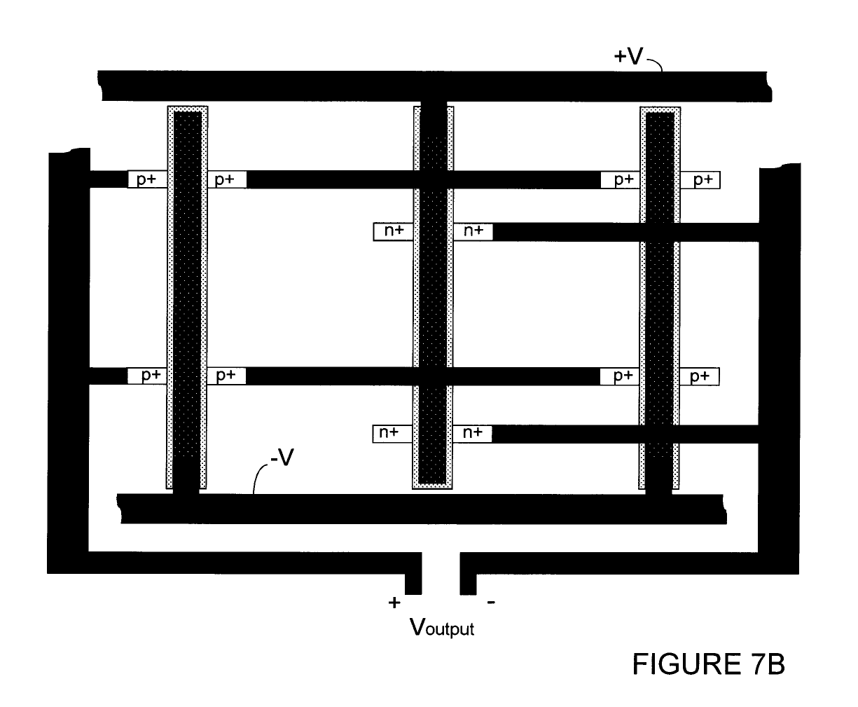

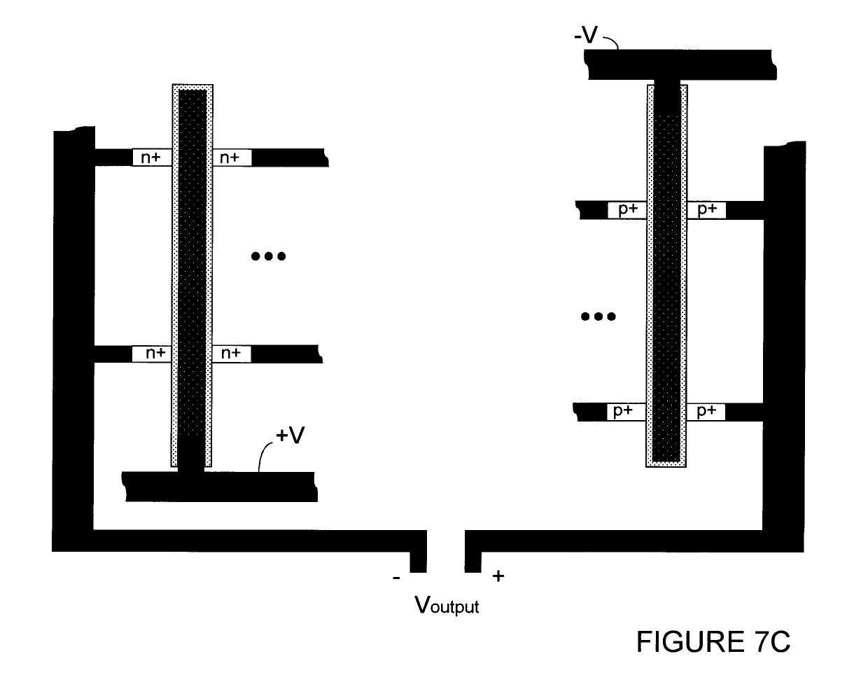

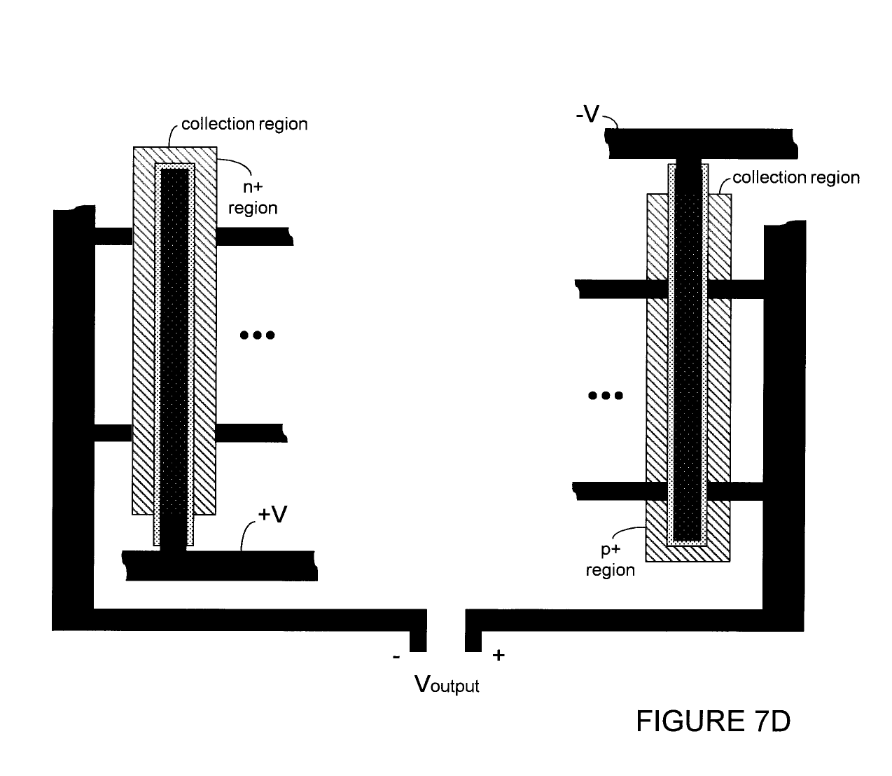

The solar cell may include more than two sub-cells. For example, in one embodiment, the solar cell includes three sub-cells. (See, for example, FIGS. 7A and 7B). Indeed, the solar cell may include any number of sub-cells (for example, four to ten sub-cells). Further, a plurality of sub-cells may couple to a first voltage (for example, a positive voltage) and a plurality may couple to a second voltage (for example, a negative voltage). (See, FIGS. 7C and 7D). In one embodiment, an equal number of sub-cells couple to the first and second voltages. In another embodiment, more sub-cells couple to a positive voltage. In yet another embodiment, more sub-cells couple to a negative voltage.

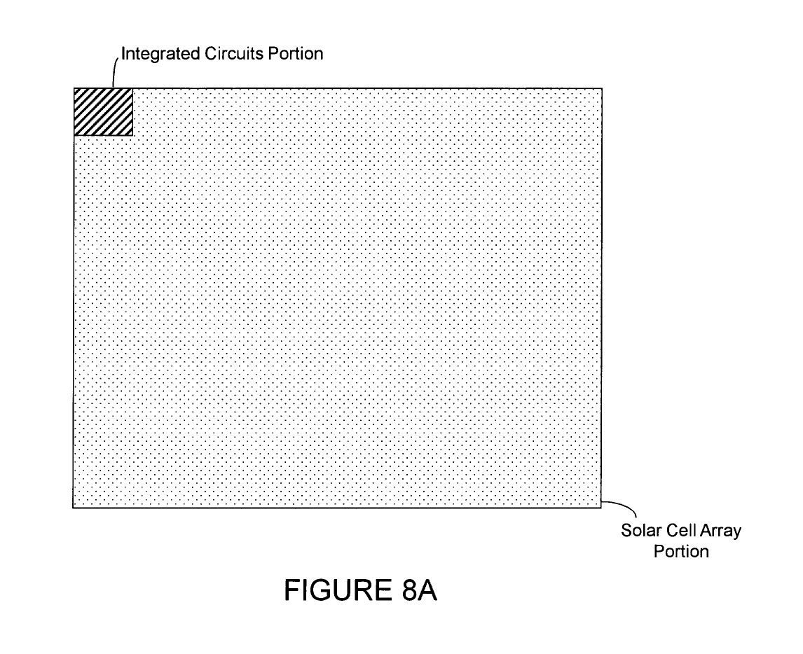

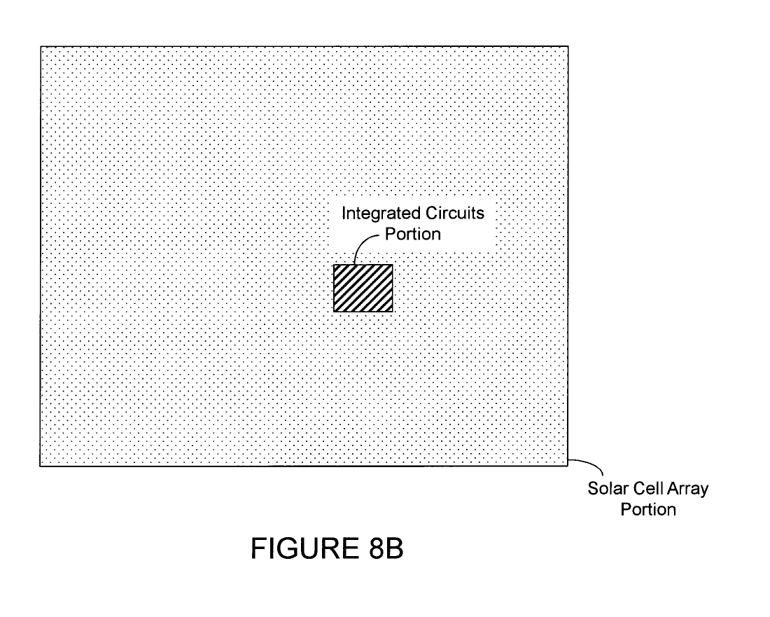

The solar cell and solar cell array of the present inventions may be fabricated using standard and well-known manufacturing processes and techniques. Moreover, where the die/device also includes integrated circuits (for example, CMOS transistors) or other active components, such circuits and other components may be integrated or fabricated into selected portions of the die/device using standard fabrication techniques and/or the techniques employed to fabricate the solar cell and solar cell array. (See, for example, FIGS. 8A and 8B). The integrated circuits or other active components may be employed to control the operation and/or output of the energy generation portion of the die/device. In one embodiment, the energy generation portion of the die/device is employed to provide electrical power to the integrate circuits or other active components.

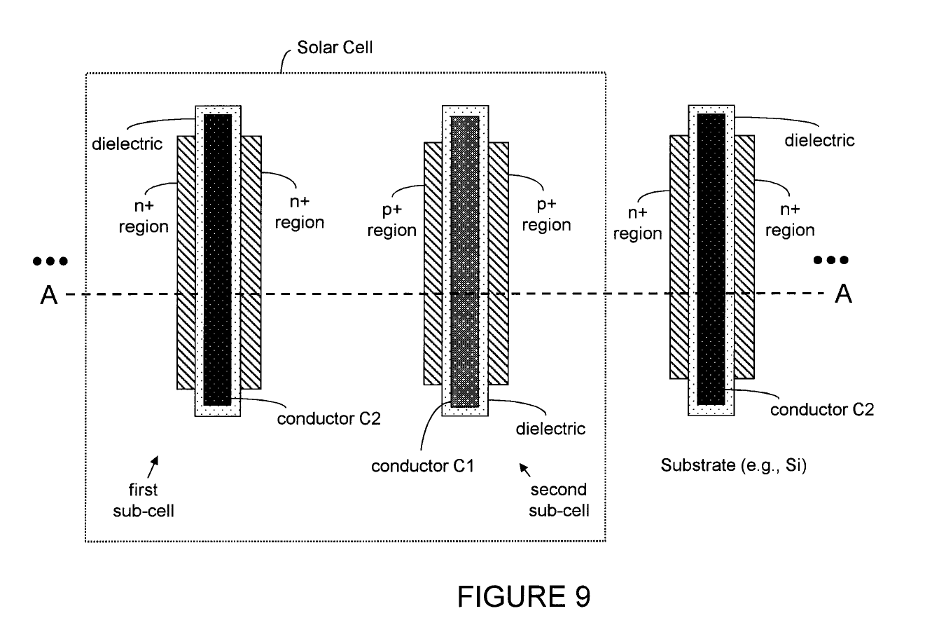

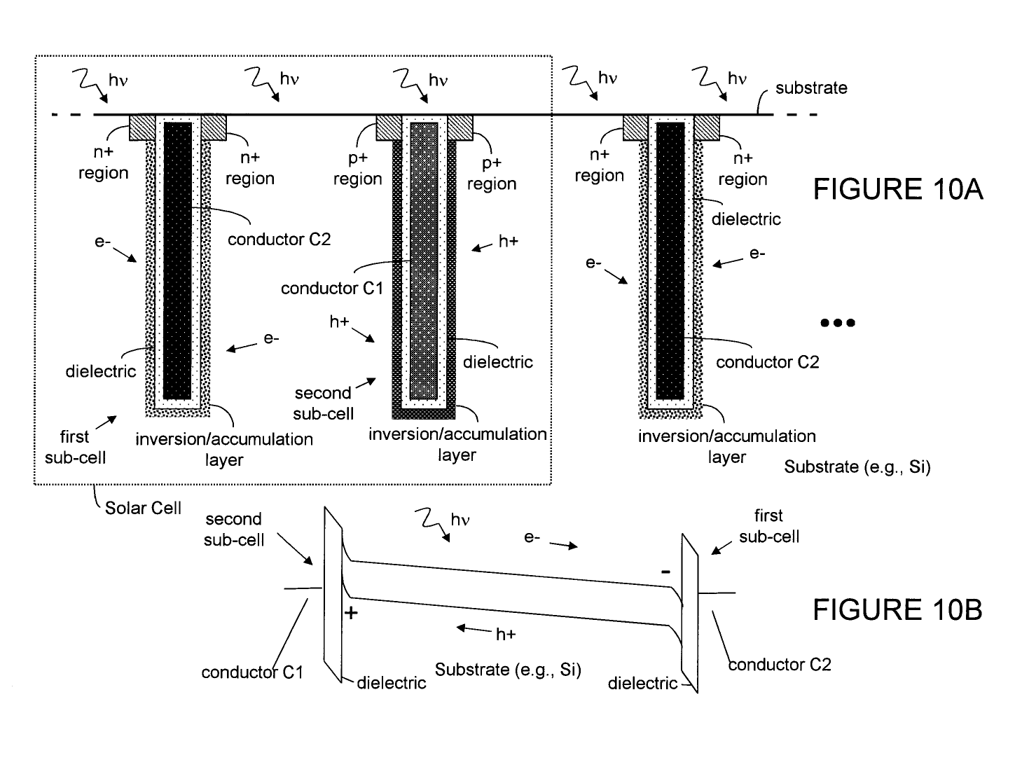

With reference to FIG. 9, in another embodiment, the conductors of the sub-cells of the solar cell consist of different materials. As such, in this embodiment, the conductors of the sub-cells include different (i) work functions and/or (ii) charges contained therein. The charges may be also embedded into the dielectrics of the first and second sub cells. In this way, one of the sub-cells of the solar cell will have a tendency to attract electrons (e−) and the other of the sub-cells will have a tendency to attract holes (h+). (See, for example, FIGS. 10A and 10B).

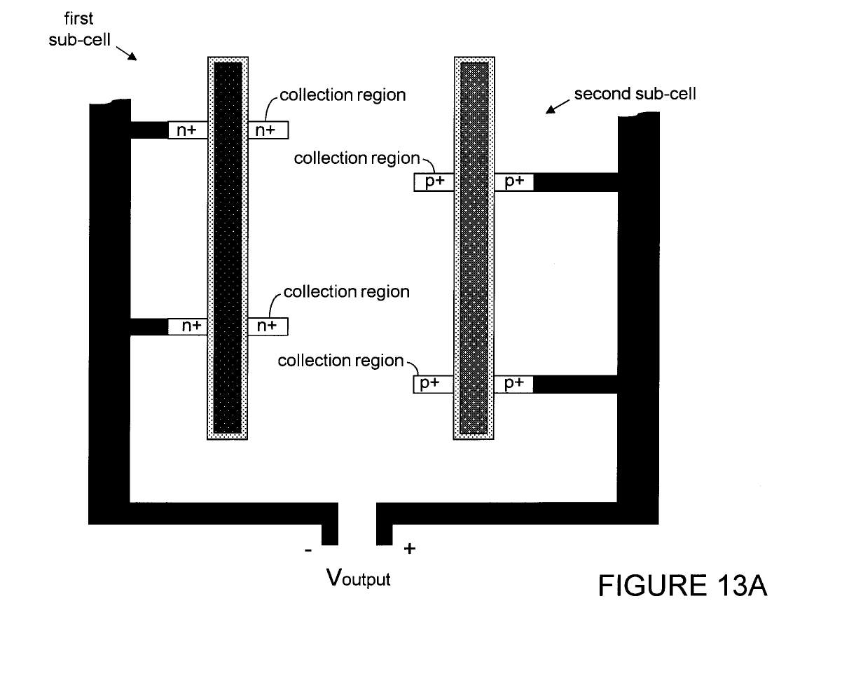

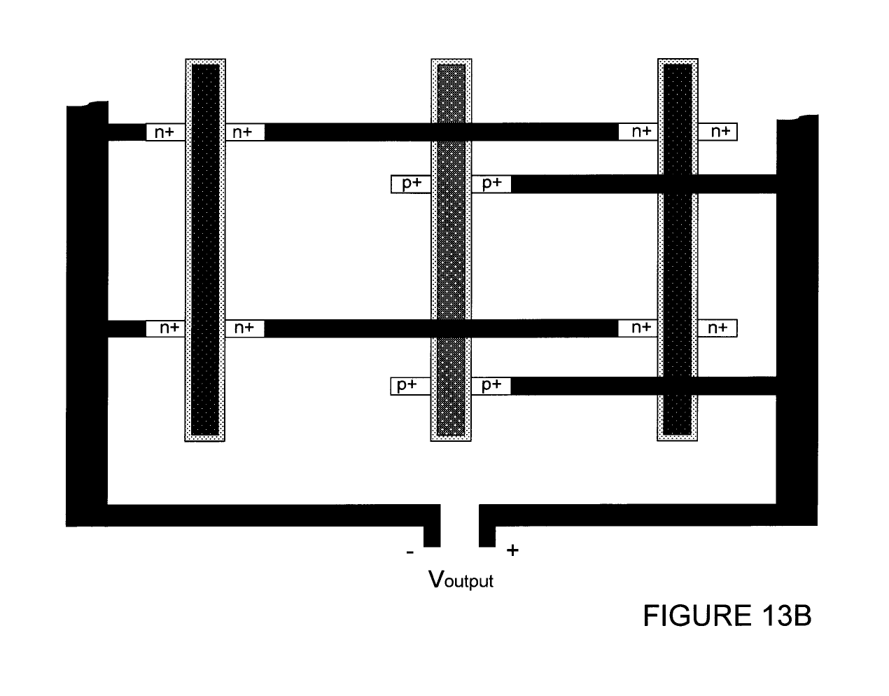

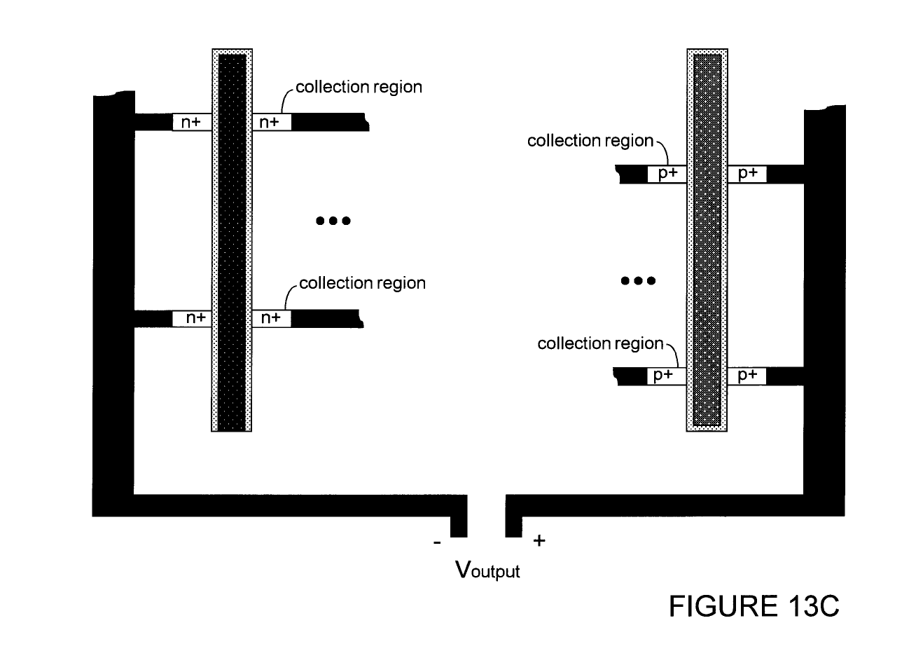

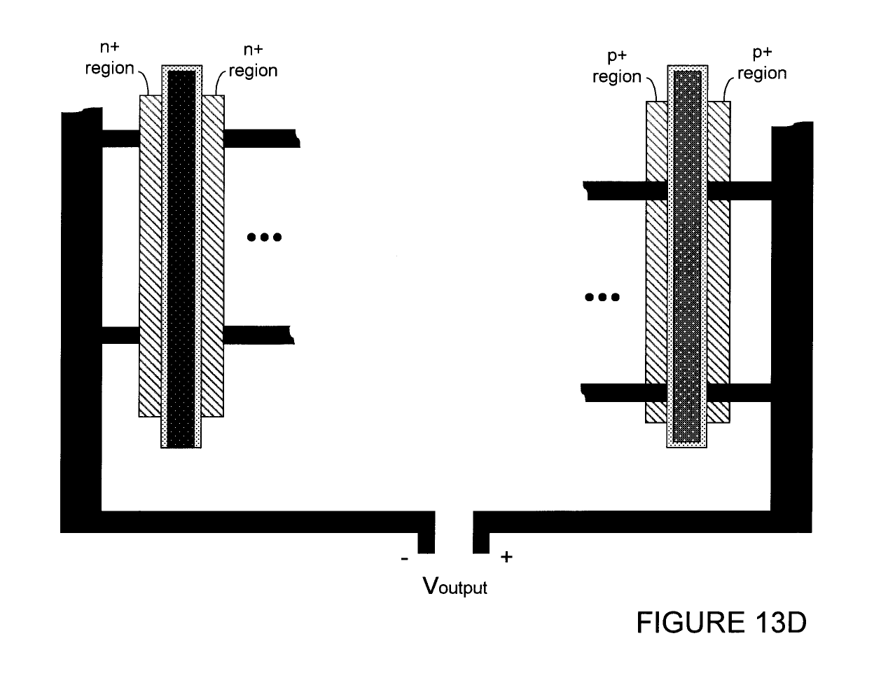

In operation, in response to incident photons from the one or more light sources (for example, the sun), electrons (e−) and holes (h+) are generated within the substrate. (See, FIGS. 10A and 10B). The conductor Cl consists of a material(s) having (i) a first work function and/or (ii) first charges therein and the conductor C2 consists of a material(s) having (i) a second work function and/or (ii) second charges therein. First and second charges may be also embedded into the dielectrics of the first and second sub cells respectively. As such, the electrons (e−) may be attracted more to the first sub-cell and the holes (h+) may be attracted more to the second sub-cell. Thereafter, many of electrons (e−) tend to move towards the n+ region(s) via the inversion or accumulation layer which forms juxtaposed the dielectric layer or material of the first sub-cell of the solar cell. Similarly, many of the holes (h+) tend to move towards the p+ region(s) via the inversion or accumulation layer which forms juxtaposed the dielectric layer or material of the second sub-cell of the solar cell. The inversion or accumulation layers provide a low resistance path for the movement of electrons (e−) and holes (h+), generated within the substrate in response to the incident photons, to the n+ region and the p+ region, respectively. The n+ region of the first sub-cell and the p+ region of the second sub-cell are electrically coupled to the output (Vₒᵤₜₚᵤₜ) of the solar cell. (See, for example, FIGS. 13A-13D).

Notably, where the substrate includes little to no impurities and/or little to no additional doping relative to conventional IC substrates, the carrier lifetime may be quite high. Moreover, any interface defects may be screened by the inversion or accumulation layers associated with the sub-cells.

In one embodiment, the conductors of this embodiment are not coupled to the first voltage (e.g., V+) or second voltage (e.g., V−). In another embodiment, the conductors of the sub-cells are coupled to one of the voltages—as discussed above in connection with the embodiments of FIGS. 1A-8B). In yet another embodiment, the conductor(s) of a subset of the sub-cells are coupled to a voltage. For example, a subset of the sub-cells is coupled to the first voltage (e.g., V+) and a subset of the sub-cells is coupled to the second voltage (e.g., V−). In another example, all or a subset of sub-cells are coupled to the first voltage (e.g., V+ or V—) and none of the sub-cells are coupled to a second voltage. All permutations and combinations thereof are intended to fall within the scope of the present inventions.

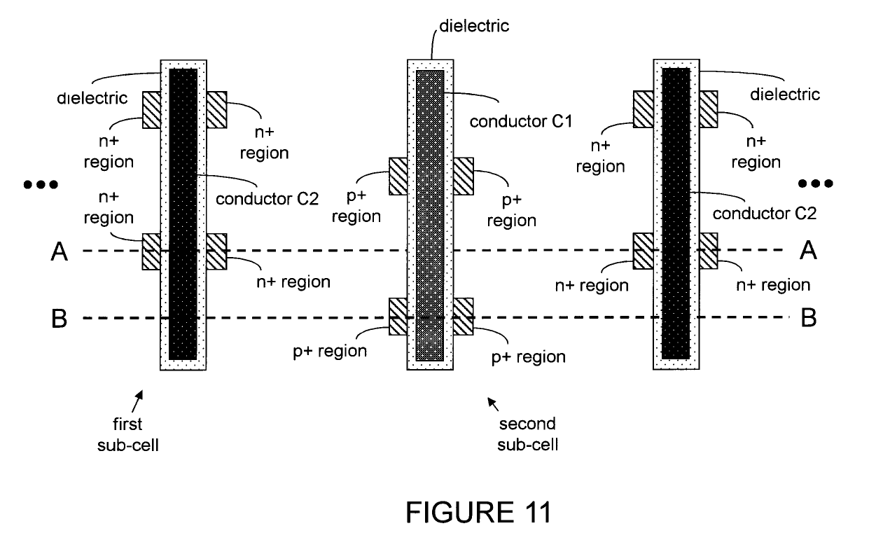

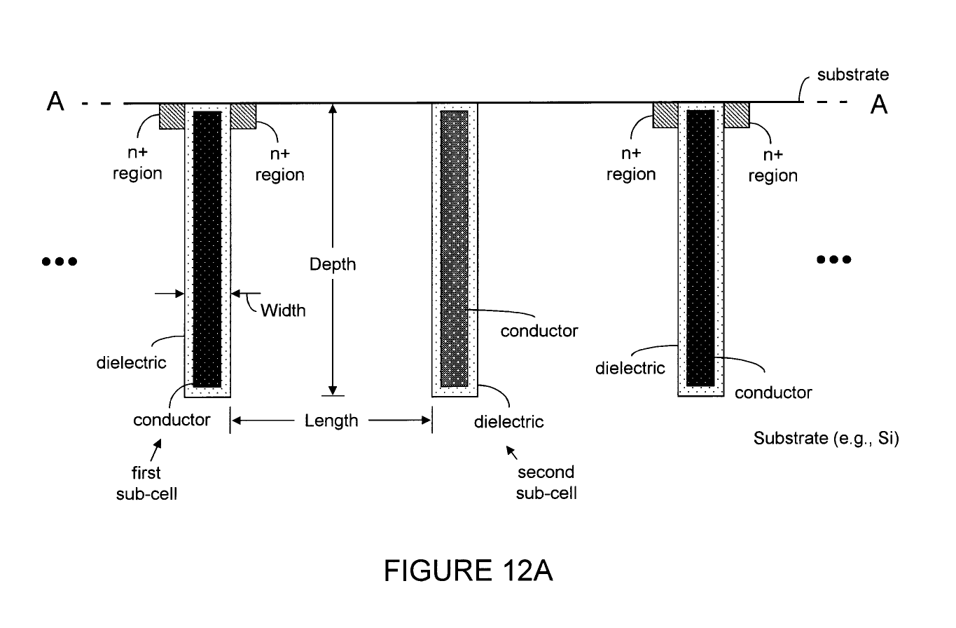

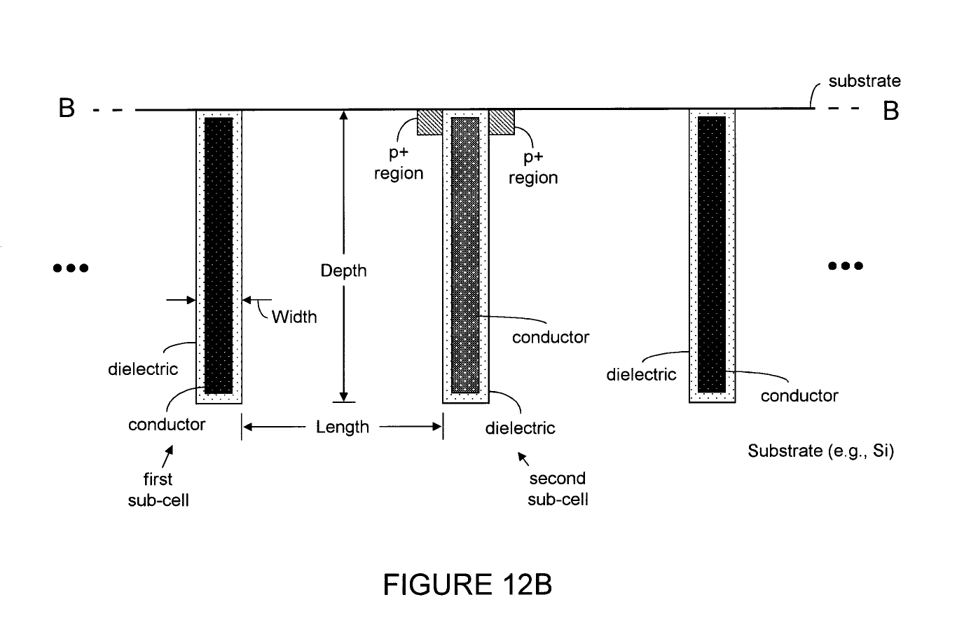

Notably, the collection regions (illustrated as an n+ region of the first sub-cell and a P+ region of the second sub-cell) may be formed substantially around the conductor-dielectric structure (see, for example, FIGS. 9 and 10A) or may include a plurality of sub-regions or “islands” at predetermined locations (see, for example, FIGS. 11, 12A and 12B). All configurations are intended to fall within the scope of the present inventions.

The solar cell may include more than two sub-cells. For example, in one embodiment, the solar cell includes three sub-cells. (See, for example, FIG. 13B). Indeed, the solar cell may include any number of sub-cells (for example, four to ten sub-cells). (See, for example, FIGS. 13C and 13D).

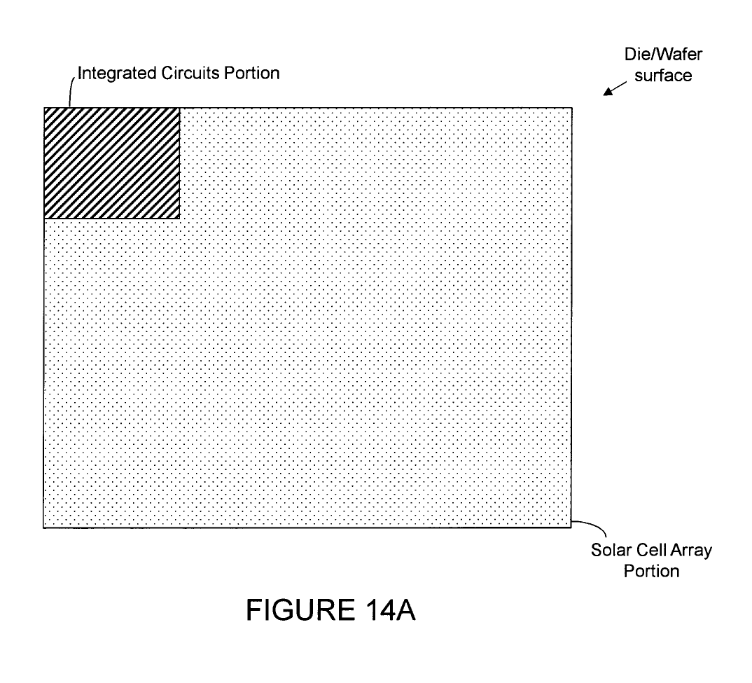

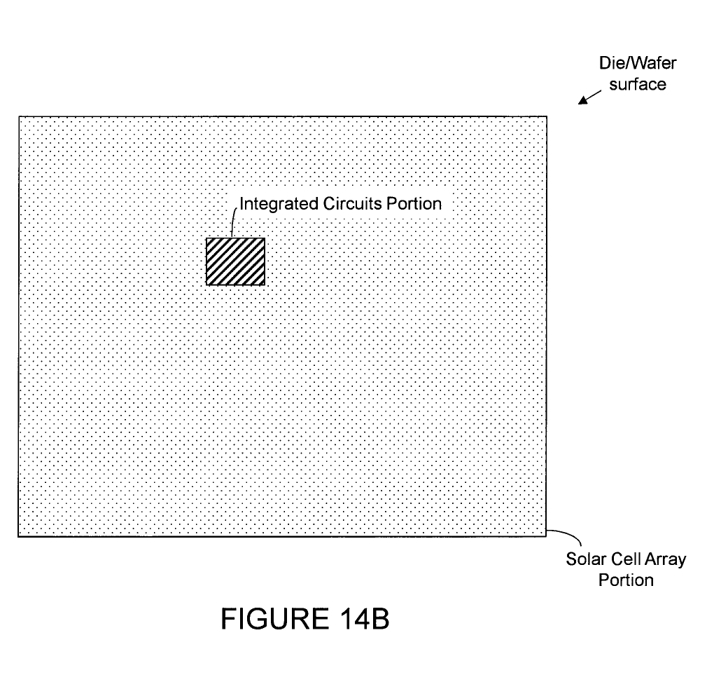

As noted above, the solar cell and solar cell array of the present inventions may be fabricated using standard and well-known manufacturing processes and techniques. Moreover, where the die/device also includes integrated circuits (for example, CMOS transistors) or other active components, such circuits and other components may be integrated or fabricated into selected portions of the die/device using standard fabrication techniques and/or the techniques employed to fabricate the solar cell and solar cell array (which includes a plurality of solar cells). (See, for example, FIGS. 14A and 14B). The integrate circuits or other active components may be employed to control the operation and/or output of the energy generation portion of the die/device. In one embodiment, the energy generation portion of the die/device is employed to provide electrical power to the integrate circuits or other active components.

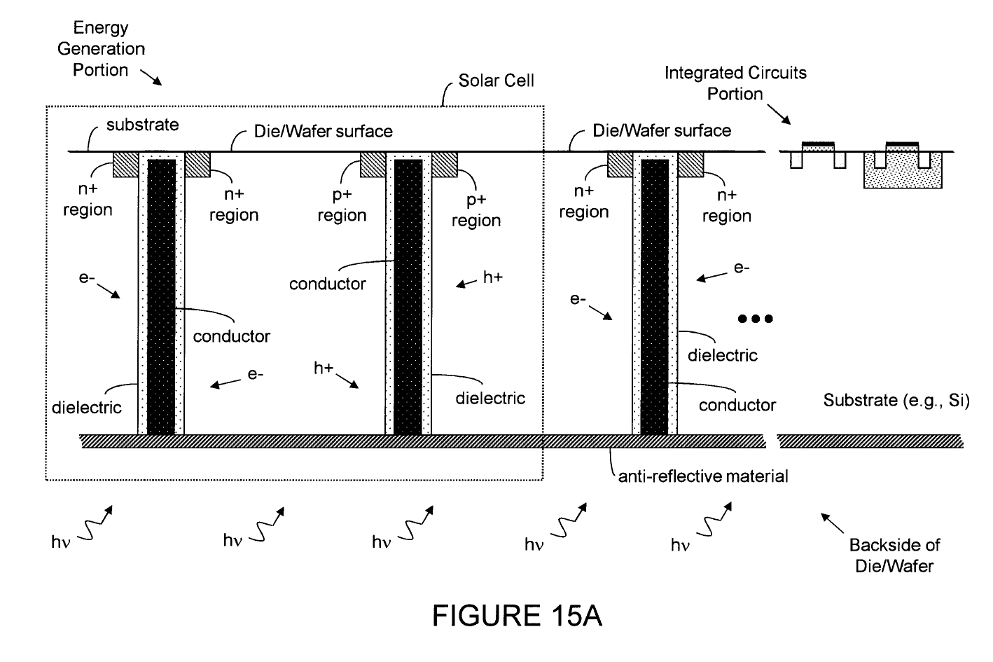

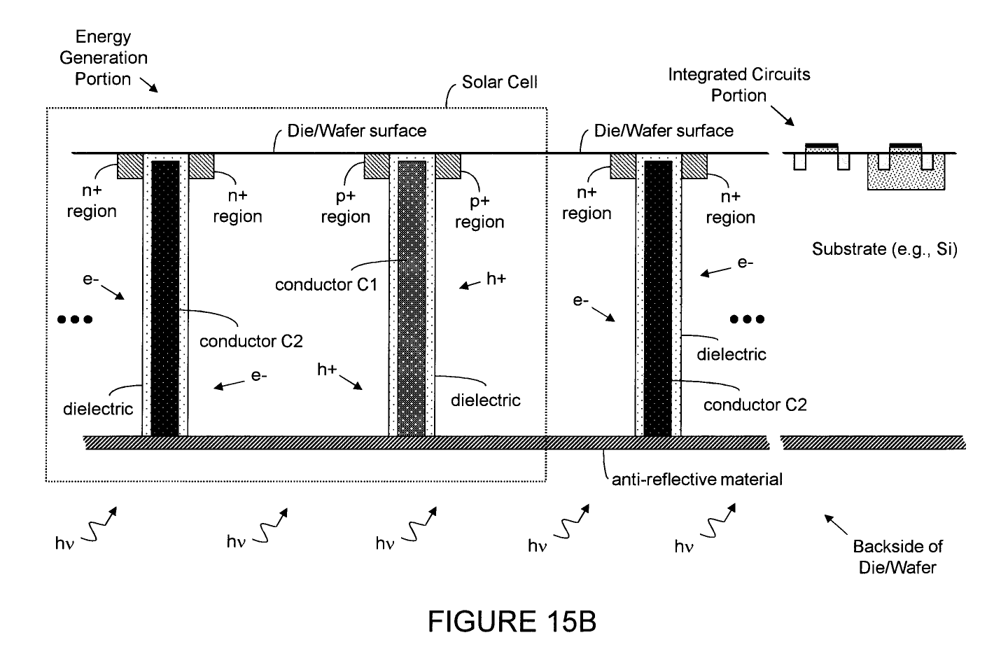

As stated above, the solar cell, solar cell array and/or die/device (including the solar cell or solar cell array) may include an anti-reflective material disposed there over or thereon. In one embodiment, an anti-reflective material may be disposed on or over the backside of the die/wafer wherein the backside of the die/wafer is exposed to incident light (for example, solar light). (See, for example, FIGS. 15A and 15B). In this embodiment, any or all of the solar cell embodiments may be employed—including conductors consisting of the same material(s) (see FIG. 15A) or different materials wherein the conductors of the sub-cells include different (i) work functions and/or (ii) charges contained therein (see, FIG. 15B). The charges may be also embedded into the dielectrics of the first and second sub cells. All of the embodiments described herein may be implemented in the configuration where the backside of the die/wafer is exposed to incident light (for example, solar light). For the sake of brevity, a separate discussion of each embodiment is not provided.

Notably, the die/device may also include integrated circuits (for example, CMOS transistors) or other active components. (See, “integrated circuit portion” of FIGS. 15A and 15B). As noted above, such circuits and other components may be integrated or fabricated into selected portions of the die/device using standard fabrication techniques and/or the techniques employed to fabricate the solar cell and solar cell array (which includes a plurality of solar cells). (See, for example, FIGS. 14A and 14B).

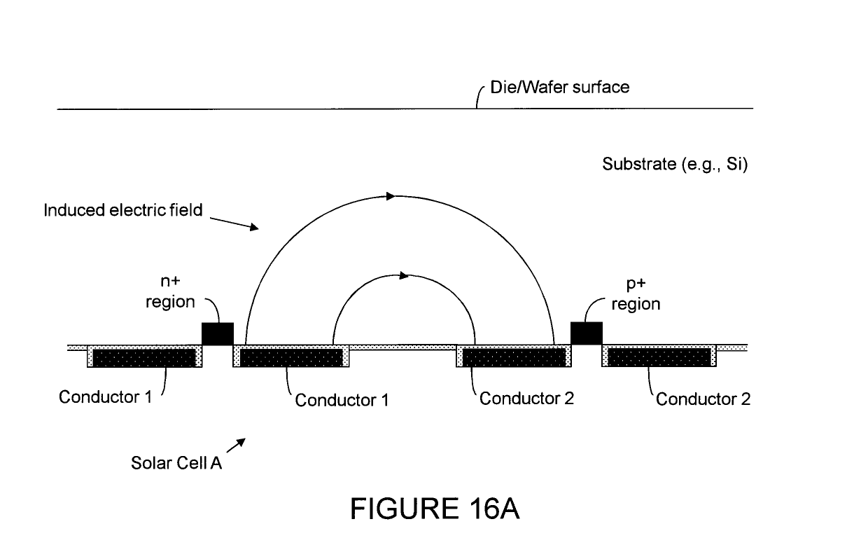

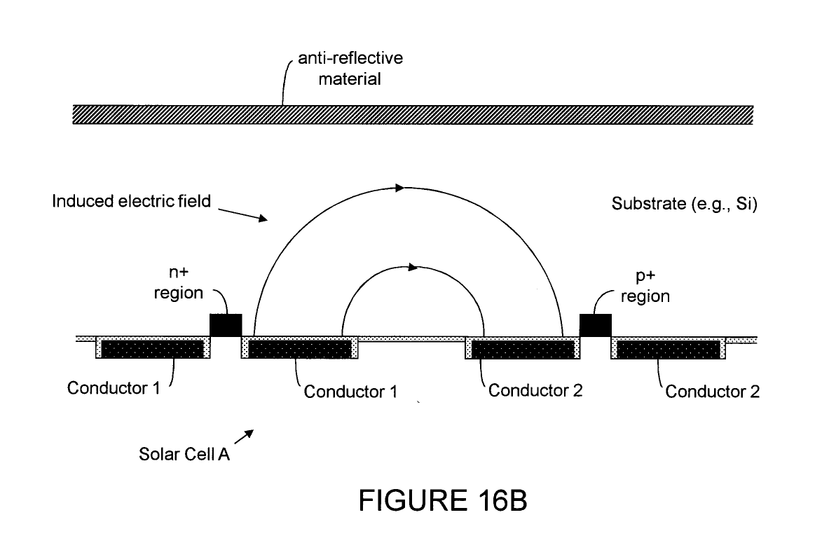

In another embodiment, the conductors are arranged laterally. (See, FIGS. 16A and 16B). In this embodiment an electric field is formed between the conductors of the solar cell A—here, conductor 1 and conductor 2. Notably, the conductors adjacent to the conductors of the solar cell A may be conductors of the solar cell A or of adjacent solar cells. Thus, in this embodiment, the solar cell may include two or more conductors.

Briefly, the conductor may be a material that provides or facilitates a charge to form therein or thereon—for example, a metal (for example, aluminum or copper), metal compound and/or a doped semiconductor (for example, silicon doped with donor or acceptor impurities).

With continued reference to FIGS. 16A and 16B, the collection regions (n+ and p+ regions) may be provided to facilitate integration and acquisition of the charge developed in the substrate as a result of incident light. Briefly, an n-type semiconductor material which provides or forms an n+ region that is juxtaposed the dielectric material associated with conductor 1. Similarly, a p-type semiconductor material which provides or forms a p+ region that is juxtaposed the dielectric material with conductor 2. The n-type semiconductor material may be formed from or by doping a semiconductor (for example, silicon) with an n-type impurity (for example, phosphorus or arsenic). The p-type semiconductor material may be formed from or by doping a semiconductor (for example, silicon) with an n-type impurity (for example, boron).

Notably, the substrate may be one or more materials from the Group IV semiconductor including silicon (for example, bulk-silicon substrate), germanium, and silicon carbide or semiconductor-on-insulator substrate (for example, and silicon-on-insulator). The substrate may be an intrinsic material or a material having impurities, for example, n-type or p-type materials.

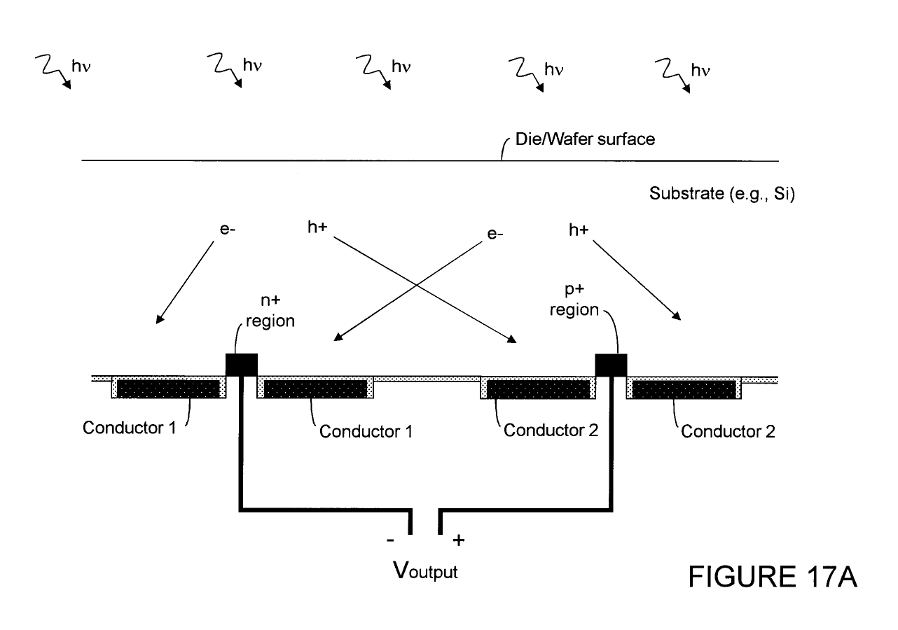

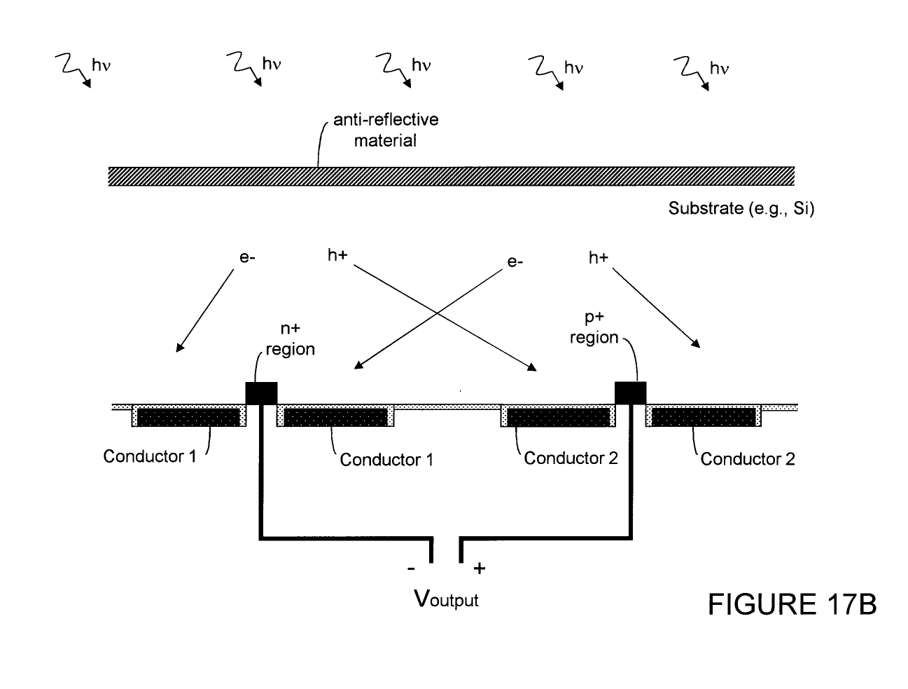

With reference to FIGS. 16A, 16B, 17A and 17B, in operation, an electric field is induced between the conductors of the solar cell. In response to incident photons from the one or more light sources (for example, the sun), electrons (e−) and holes (h+) are generated within the substrate. As such, in view of the induced electric field, electrons (e−) are attracted to the conductor 1 and the holes (h+) are attracted to conductor 2.

The n+ region juxtaposed conductor 1 and the p+ region juxtaposed conductor 2 are electrically coupled to the output (Vₒᵤₜₚᵤₜ) of the solar cell. (See, for example, FIGS. 17A and 17B). Notably, the n+ region of the first sub-cell and the P+ region of the second sub-cell may be formed substantially around the conductor-dielectric structure or may be formed as “islands” at selected locations. All configurations are intended to fall within the scope of the present inventions.

In one embodiment, conductor 1 and conductor 2 of the solar cell may consist of the same or different materials. Where conductor 1 consists of a material which is different from the material of conductor 2, the conductors of the sub-cells may include different (i) work functions and/or (ii) charges contained therein. The charges may be also embedded into the dielectrics of the first and second sub cells. In this way, one of the conductors of the solar cell will have a tendency to attract electrons (e−) and the other conductor will have a tendency to attract holes (h+).

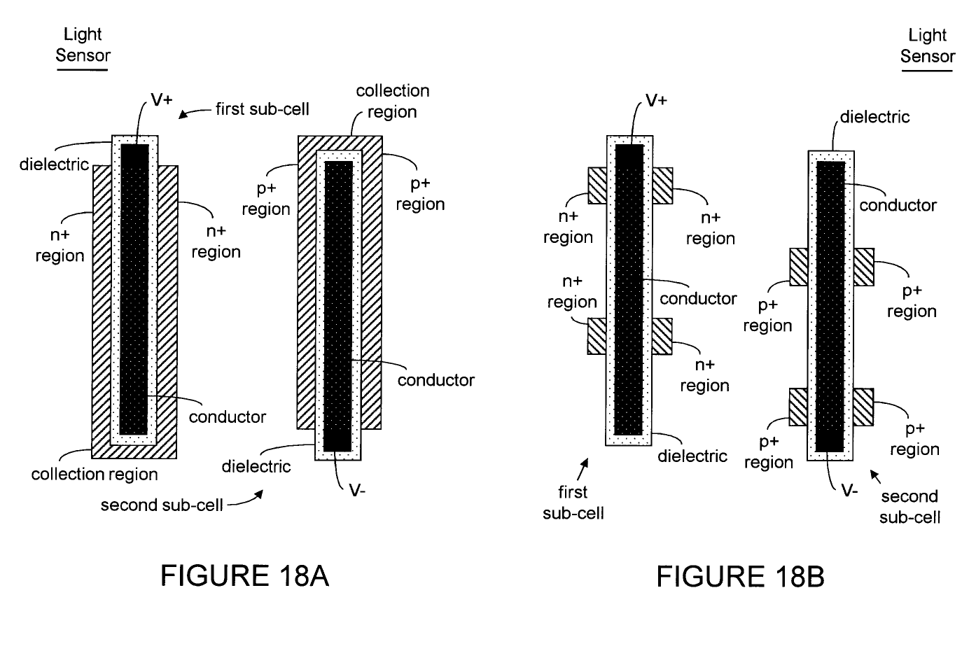

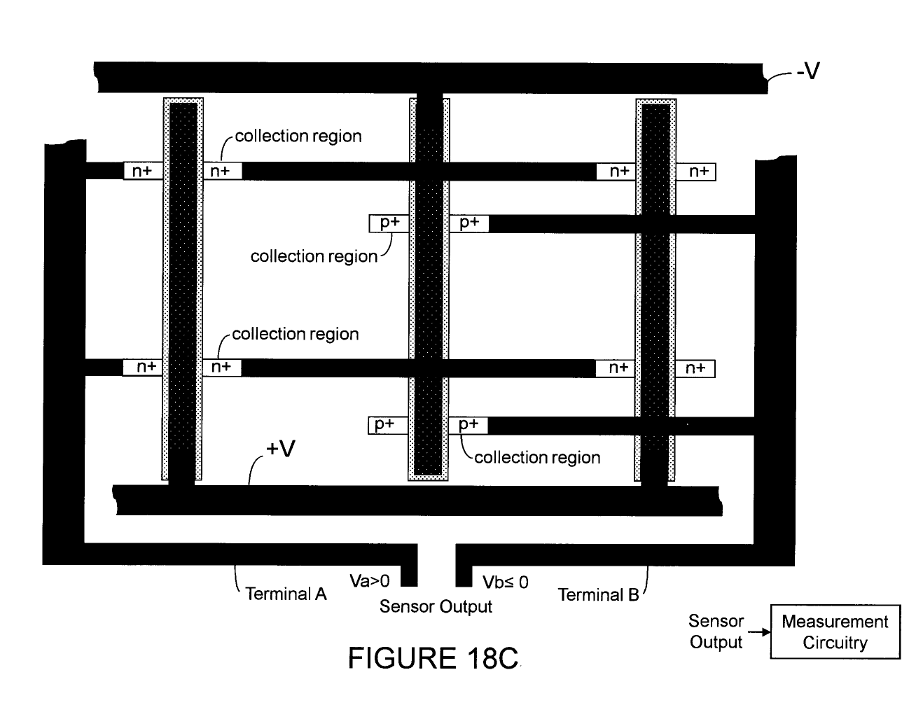

In another aspect, the present inventions are directed to a light sensor comprised of one or more of the solar cells described and/or illustrated herein. For example, with reference to FIGS. 18A-18C, in one embodiment, the light sensor includes any two or more sub-cells as described and/or illustrated herein wherein the collection regions are coupled to the sensor output. In one embodiment, in operation, a voltage Va>0 is applied to the terminal A connected to the n+ regions and a voltage Vb≦0 is applied to the terminal B connected to the p+ regions. Incident light induces a current between terminals A and B. The measurement circuitry (for example, a current type sensor such as a current sensor) may measure this current to detect the light and/or intensity of the light. (See, FIG. 18C). The measurement circuitry may be any circuitry now known or later developed to measure current; such circuitry may implement any technique now known or later developed to detect and/or measure current output by the light sensor.

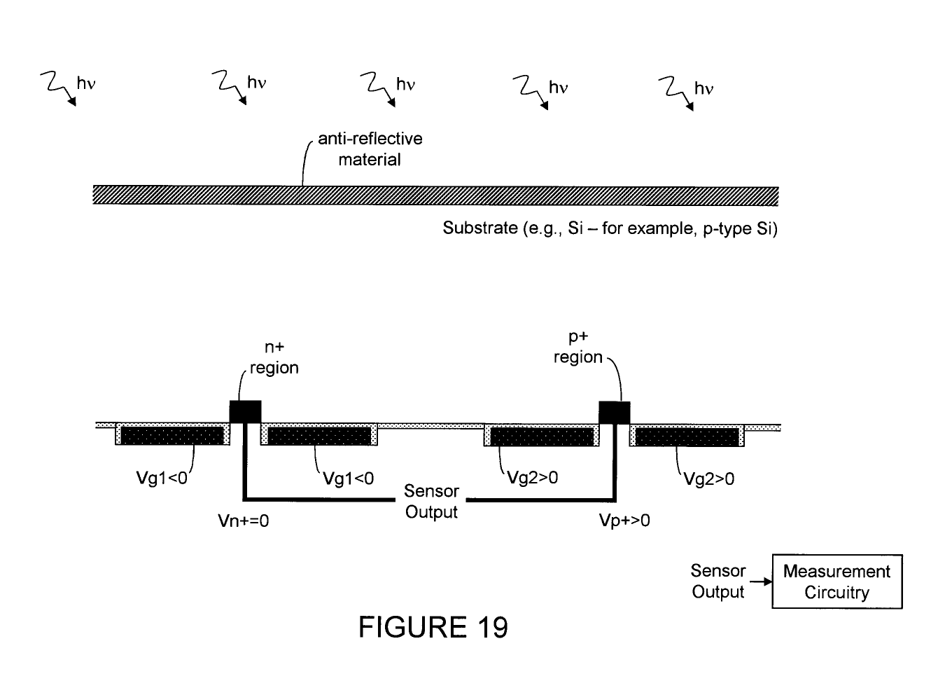

Notably, the light sensor may implement any of the sub-cells, or features thereof, described and/or illustrated herein. For example, in another embodiment, with reference to FIG. 19, two or more sub-cells (of the lateral type) may form a light sensor. In operation, in one embodiment, the n+ region may be placed at a fixed potential (for example, ground), a positive voltage applied to p+ region, a negative voltage Vg1 applied to the gate adjacent to n+and a positive voltage Vg2 applied to the gate Vg2 adjacent to p+region. Under these circumstances, a depletion layer forms or is created around p+ region and a small current may flow between n+ and p+ terminals before a sufficient amount of light is incident on the sensor (i.e., the light is “off”). When a sufficient amount of light is incident on the sensor (i.e., the light is “on”), electrons generated or created by incident photons will accumulate under the gate adjacent to p+ region. In response, a relatively large current is triggered or generated between n+ and p+ contacts. Such current may be detected and/or measured via measurement circuitry (for example, a current type sensor). In one embodiment, the measurement circuitry measures or detects the current output by the light sensor to measure or detect the light and/or intensity of the light.

Notably, the measurement circuitry may be any circuitry now known or later developed to detect, determine and/or measure current; such circuitry may implement any technique now known or later developed to detect, determine and/or measure current output by the light sensor. For example, in one embodiment, a current type sensor (for example, current meter) detects the light when the current output from the light sensor exceeds a predetermined threshold. In addition thereto, or in lieu thereof, a current type sensor may detect the intensity of the light by measuring the maximum amplitude of the current output of the light sensor. Indeed, the current type sensor may measure the intensity over time by measuring and storing the amplitude of the current output of the light sensor over time.

There are many inventions described and illustrated herein. While certain embodiments, features, attributes and advantages of the inventions have been described and illustrated, it should be understood that many others, as well as different and/or similar embodiments, features, attributes and advantages of the present inventions, are apparent from the description and illustrations. As such, the above embodiments of the inventions are merely exemplary. They are not intended to be exhaustive or to limit the inventions to the precise forms, techniques, materials and/or configurations disclosed. Many modifications and variations are possible in light of this disclosure. It is to be understood that other embodiments may be utilized and operational changes may be made without departing from the scope of the present inventions. As such, the scope of the inventions is not limited solely to the description above because the description of the above embodiments has been presented for the purposes of illustration and description.

Importantly, the present inventions are neither limited to any single aspect nor embodiment, nor to any combinations and/or permutations of such aspects and/or embodiments. Moreover, each of the aspects of the present inventions, and/or embodiments thereof, may be employed alone or in combination with one or more of the other aspects and/or embodiments thereof. For the sake of brevity, many of those permutations and combinations will not be discussed and/or illustrated separately herein.

Notably, the solar cells of the present inventions may be implemented in any architecture as well as in conjunction with any type of integrated circuitry, whether now known or later developed; all such configurations are intended to fall within the scope of the present inventions. Further, any manufacturing technique, whether now known or later developed, may be employed to fabricate the solar cell, solar cell array (which includes a plurality of solar cells) and/or solar cell array-integrated circuit device embodiments of the present inventions; all such techniques are intended to fall within the scope of the present inventions.

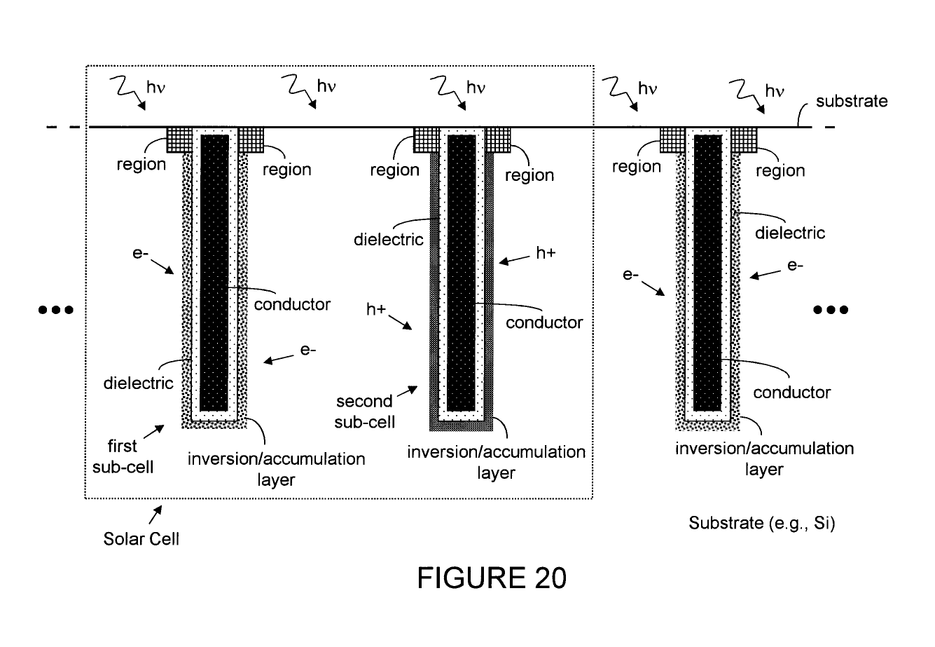

Further, the collection regions (illustrated as n+ and p+ regions) in the embodiments described and/or illustrated herein may be a doped semiconductor (for example, silicon doped with donor or acceptor impurities—as the case may be). Alternatively, one or more (or all) of such collection regions may be comprised of a metal (for example, aluminum or copper) or metal compound. (See, for example, FIG. 20).

It should be noted that the term “circuit” may mean, among other things, a single component or a multiplicity of components (whether in integrated circuit form or otherwise), which are active and/or passive, and which are coupled together to provide or perform a desired function. The term “circuitry” may mean, among other things, a circuit (whether integrated or otherwise), a group of such circuits, one or more processors, one or more state machines, one or more processors implementing software, one or more gate arrays, programmable gate arrays and/or field programmable gate arrays, or a combination of one or more circuits (whether integrated or otherwise), one or more state machines, one or more processors, one or more processors implementing software, one or more gate arrays, programmable gate arrays and/or field programmable gate arrays. The term “data” may mean, among other things, a current or voltage signal(s) whether in an analog or a digital form, which may be a single bit (or the like) or multiple bits (or the like).

It should be further noted that the solar cell structures, circuits and/or circuitry disclosed herein may be described using computer aided design tools and expressed (or represented), as data and/or instructions embodied in various computer-readable media, for example, in terms of their behavioral, register transfer, logic component, transistor, layout geometries, and/or other characteristics. Formats of files and other objects in which such circuit expressions may be implemented include, but are not limited to, formats supporting behavioral languages such as C, Verilog, and HLDL, formats supporting register level description languages like RTL, and formats supporting geometry description languages such as GDSII, GDSIII, GDSIV, CIF, MEBES and any other suitable formats and languages. Computer-readable media in which such formatted data and/or instructions may be embodied include, but are not limited to, non-volatile storage media in various forms (e.g., optical, magnetic or semiconductor storage media) and carrier waves that may be used to transfer such formatted data and/or instructions through wireless, optical, or wired signaling media or any combination thereof. Examples of transfers of such formatted data and/or instructions by carrier waves include, but are not limited to, transfers (uploads, downloads, e-mail, etc.) over the Internet and/or other computer networks via one or more data transfer protocols (e.g., HTTP, FTP, SMTP, etc.). The present inventions are also directed to such representation of the circuitry described herein, and/or techniques implemented thereby, and, as such, are intended to fall within the scope of the present inventions.

Indeed, when received within a computer system via one or more computer-readable media, such data and/or instruction-based expressions of the above described structures, circuits and/or circuitry may be processed by a processing entity (e.g., one or more processors) within the computer system in conjunction with execution of one or more other computer programs including, without limitation, net-list generation programs, place and route programs and the like, to generate a representation or image of a physical manifestation of such circuits. Such representation or image may thereafter be used in device fabrication, for example, by enabling generation of one or more masks that are used to form various components of the circuits in a device fabrication process.

Moreover, the various solar cell structures, circuits and/or circuitry, as well as techniques, disclosed herein may be represented via simulations and simulation instruction-based expressions using computer aided design, simulation and/or testing tools. The simulation of the solar cells and solar cell arrays of the present inventions, manufacturing processes to fabricate such cells and arrays, and/or techniques implemented thereby, may be implemented by a computer system wherein characteristics and operations of such circuitry, and techniques implemented thereby, are simulated, imitated, replicated, analyzed and/or predicted via a computer system. The present inventions are also directed to such simulations and testing of the inventive solar cells and solar cell arrays, efficiencies thereof, and/or techniques implemented thereby, and, as such, are intended to fall within the scope of the present inventions. The computer-readable media and data corresponding to such simulations and/or testing tools are also intended to fall within the scope of the present inventions.

What is claimed is:

1. A solar cell disposed in a substrate, the solar cell comprising:
a first sub-cell, disposed in the substrate, including:
a first conductor disposed in the substrate, wherein the first conductor is adapted to receive a first predetermined voltage;
a first collection region disposed in the substrate; and
a first insulating layer disposed on the first conductor and (i) between the first conductor and the first collection region and (ii) between the first conductor and the substrate; and
a second sub-cell, disposed in the substrate and separated from the first sub-cell by a predetermined length, the second sub-cell includes:
a second conductor disposed in the substrate, wherein the second conductor is adapted to receive a second predetermined voltage;
a second collection region disposed in the substrate; and
a second insulating layer disposed (i) between the second conductor and the second collection region and (ii) between the second conductor and the substrate; and
wherein:
a ratio of a depth of the conductor of the first sub-cell within the substrate to a width of the conductor of the first sub-cell within the substrate is greater than or equal to 10:1; and
the predetermined length between the first sub-cell and the second sub-cell is greater than the sum of the widths of depletion/inversion layers formed in relation to the first and second sub-cells during operation.

2. The solar cell of claim 1 wherein:
the first collection region is disposed substantially around and on the first insulating layer; and
the second collection region is disposed substantially around and on the second insulating layer.

3. The solar cell of claim 1 wherein:
the first collection region includes a plurality of sub-regions disposed around and on the first insulating layer; and
the second collection region includes a plurality of sub-regions disposed around and on the second insulating layer.

4. The solar cell of claim 1 wherein:
the first insulating layer surrounds the first conductor within the substrate to insulate the first conductor from the first collection region and the substrate; and
the second insulating layer surrounds the second conductor within the substrate to insulate the second conductor from the second collection region and the substrate.

5. The solar cell of claim 1 wherein the first collection region is juxtaposed the first insulating layer and the second collection region is juxtaposed the second insulating layer.

6. The solar cell of claim 1 wherein the ratio of the depth of the conductor of the first sub-cell in the substrate to the width of the conductor of the first sub-cell is greater than or equal to 25:1.

7. The solar cell of claim 1 wherein the ratio of the depth of the conductor of the first sub-cell in the substrate to the width of the conductor of the first sub-cell is greater than or equal to 50:1.

8. The solar cell of claim 1 further including an anti-reflective material disposed on an exposed surface of the substrate.

9. The solar cell of claim 1 wherein:
the first collection region includes a plurality of sub-regions disposed around and on the first insulating layer; and
the second collection region includes a plurality of sub-regions disposed around and on the second insulating layer wherein the plurality of sub-regions of the first collection region are laterally offset in relation to the plurality of sub-regions of the second collection region.

10. The solar cell of claim 1 wherein the first and second collection regions are coupled to an output.

11. A solar cell disposed in a semiconductor substrate, the solar cell comprising:
a first sub-cell, disposed in the semiconductor substrate, including:
a first conductor disposed in the semiconductor substrate, wherein the first conductor is adapted to receive a first predetermined voltage;
a first collection region disposed in the semiconductor substrate; and
a first insulating layer disposed on the first conductor and (i) between the first conductor and the first collection region and (ii) between the first conductor and the semiconductor substrate, wherein the first collection region is juxtaposed the first insulating layer;
a second sub-cell, disposed in the semiconductor substrate and separated from the first sub-cell by a predetermined length, the second sub-cell includes:
a second conductor disposed in the semiconductor substrate, wherein the second conductor is adapted to receive a second predetermined voltage;
a second collection region disposed in the semiconductor substrate; and
a second insulating layer disposed (i) between the second conductor and the second collection region and (ii) between the second conductor and the semiconductor substrate, wherein the second collection region is juxtaposed the second insulating layer; and
wherein a ratio of a depth of the conductor of the first sub-cell within the semiconductor substrate to a width of the conductor of the first sub-cell within the semiconductor substrate is greater than or equal to 10:1.

12. The solar cell of claim 11 wherein the first and second conductors are metal, metal compound and/or one or more semiconductors doped with one or more impurities.

13. The solar cell of claim 11 wherein the first and second collection regions are regions of the semiconductor substrate that are doped with one or more impurities.

14. The solar cell of claim 11 wherein the first and second insulating layers include silicon oxide, silicon nitride and/or combination thereof.

15. The solar cell of claim 11 wherein:
the first collection region is disposed substantially around and on the first insulating layer; and
the second collection region is disposed substantially around and on the second insulating layer.

16. The solar cell of claim 11 wherein:
the first collection region includes a plurality of sub-regions disposed around and on the first insulating layer; and
the second collection region includes a plurality of sub-regions disposed around and on the second insulating layer.

17. A solar cell system comprising:
a solar cell disposed in a semiconductor substrate, the solar cell including:
a first sub-cell, disposed in the semiconductor substrate, including:
a first conductor disposed in the semiconductor substrate, wherein the first conductor is adapted to receive a first predetermined voltage;
a first collection region disposed in the semiconductor substrate; and
a first insulating layer disposed (i) on and surrounding the first conductor within the semiconductor substrate to insulate the first conductor from the semiconductor substrate and (ii) between the first conductor and the first collection region to insulate the first conductor from the first collection region;
a second sub-cell, disposed in the semiconductor substrate and separated from the first sub-cell by a predetermined length, the second sub-cell includes:
a second conductor disposed in the semiconductor substrate, wherein the second conductor is adapted to receive a second predetermined voltage;
a second collection region disposed in the semiconductor substrate; and
a second insulating layer disposed (i) on and surrounding the second conductor within the semiconductor substrate to insulate the second conductor from the semiconductor substrate and (ii) between the second conductor and the second collection region to insulate the second conductor from the second collection region; and
wherein a ratio of a depth of the conductor of the first sub-cell within the semiconductor substrate to a width of the conductor of the first sub-cell within the semiconductor substrate and a ratio of a depth of the conductor of the second sub-cell within the semiconductor substrate to a width of the conductor of the second sub-cell within the semiconductor substrate are each greater than or equal to 10:1.

18. The system of claim 17 further including a voltage generator, coupled to the first and second conductors, to generate the first and second predetermined voltages.

19. The system of claim 18 wherein the first predetermined voltage is positive and the second predetermined voltage is negative.

20. The system of claim 17 wherein the ratio of the depth of the conductor of the first sub-cell within the semiconductor substrate to the width of the conductor of the first sub-cell within the semiconductor substrate and the ratio of the depth of the conductor of the second sub-cell within the semiconductor substrate to the width of the conductor of the second sub-cell within the semiconductor substrate are each greater than or equal to 50:1.
